(19) United States
(12) Patent Application Publication
(10) Pub. No.: US 2017/0271579 A1
(43) Pub. Date: Sep. 21, 2017

(54) MAGNETIC RANDOM ACCESS MEMORY DEVICE AND METHOD OF MANUFACTURING THE SAME

(71) Applicant: Samsung Electronics Co., Ltd., Suwon-si (KR)

(72) Inventor: Dae-Shik KIM, Hwaseong-si (KR)

(21) Appl. No.: 15/604,643

(22) Filed: May 24, 2017

Related U.S. Application Data
(62) Division of application No. 14/264,039, filed on Apr. 28, 2014.

(30) Foreign Application Priority Data
Aug. 2, 2013 (KR) 10-2013-0091970

(51) Int. Cl. H01L 43/12; H01L 43/08; H01L 27/22

(52) U.S. Cl. CPC H01L 43/12; H01L 27/228; H01L 43/08

(57) ABSTRACT

In an MRAM device, the MRAM includes a magnetic tunnel junction (MTJ) structure and a protection layer on a sidewall of the MTJ structure. The protection layer includes a fluorinated metal oxide. When an MRAM device in accordance with example embodiments is manufactured, a metal layer may be formed to cover a MTJ structure. The metal layer may be oxidized and fluorinated to form the protection layer. A free layer pattern included in the MTJ structure may not be oxidized and the metal layer may be fully oxidized. Because the free layer pattern is not oxidized, the MTJ structure has a good TMR. Because the metal layer is fully oxidized, the MRAM device may be prevented from electrical short between the free layer pattern and a fixed layer pattern.

### CROSS-REFERENCE TO RELATED APPLICATION

This U.S. non-provisional patent application is a divisional of U.S. patent application Ser. No. 14/264,039, filed Apr. 28, 2014, which application claims priority under 35 USC §119 to Korean Patent Application No. 10-2013-0091970 filed on Aug. 2, 2013 in the Korean Intellectual Property Office (KIPO), the entire disclosure of which are incorporated herein by reference.

### BACKGROUND

1. Field

Example embodiments relate to semiconductor devices and methods of manufacturing the same. More particularly, example embodiments relate to magnetic random access memory (MRAM) devices and methods of manufacturing the same.

2. Description of the Related Art

An MRAM device may include a plurality of magnetic tunnel junction (MTJ) structures. The plurality of MTJ structures may be manufactured at a low temperature in order to get a high tunneling magneto resistance (TMR). The MRAM device may benefit from a protection layer so that the plurality of MTJ structures may not be deteriorated in subsequent processes.

### SUMMARY

Example embodiments provide an MRAM device including a protection layer having desirable properties on an MTJ structure.

Example embodiments provide a method of manufacturing an MRAM device including a protection layer having desirable properties on an MTJ structure.

According to example embodiments, there is provided an MRAM device. The MRAM includes a magnetic tunnel junction (MTJ) structure and a protection layer on a sidewall of the MTJ structure. The protection layer includes a fluorinated metal oxide.

In example embodiments, the protection layer may include aluminum oxide including fluorine.

In example embodiments, the MRAM device may further include a lower electrode beneath the MTJ structure and an upper electrode on the MTJ structure.

In example embodiments, the protection layer may be also formed on sidewalls of the lower and upper electrodes.

In example embodiments, the MRAM device may further include a bit line electrically connected to the upper electrode, a transistor electrically connected to the lower electrode and a source line electrically connected to the transistor.

In example embodiments, the transistor may include a gate structure on a substrate and an impurity region at an upper portion of the substrate adjacent to the gate structure. The lower electrode and the source line may be electrically connected to the impurity region.

In example embodiments, the MTJ structure may include a fixed layer pattern, a tunnel barrier layer pattern and a free layer pattern sequentially stacked.

In example embodiments, the fixed layer pattern and the free layer pattern may include a metal. The free layer pattern may not substantially include oxygen.

According to example embodiments, there is provided a method of manufacturing an MRAM device. In the method, an MTJ structure is formed on a substrate. A metal layer is formed to cover the MTJ structure. The metal layer is oxidized and fluorinated.

In example embodiments, the metal layer may include aluminum.

In example embodiments, when the metal layer is oxidized and fluorinated, oxygen plasma and a fluorine source may be used, respectively.

In example embodiments, the fluorine source may include polytetrafluoroethylene.

In example embodiments, before the metal layer is oxidized and fluorinated, the substrate on which the MTJ structure is formed may be loaded into a chamber including the oxygen plasma and the fluorine source.

In example embodiments, the fluorine source may include polytetrafluoroethylene.

The fluorine source may have a hollow cylindrical shape.

In example embodiments, before the metal layer is formed, a lower electrode may be formed on the substrate. An upper electrode may be formed on the MTJ structure. The metal layer may be formed to cover the lower electrode, the MTJ structure and the upper electrode.

When an MRAM device in accordance with example embodiments is manufactured, a metal layer may be formed to cover a MTJ structure. The metal layer may be oxidized and fluorinated to form a protection layer. A free layer pattern included in the MTJ structure may not be oxidized and the metal layer may be fully oxidized. Because the free layer pattern is not oxidized, the MTJ structure has a good TMR. Because the metal layer is fully oxidized, the MRAM device may be prevented from electrical short between the free layer pattern and a fixed layer pattern.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a cross-sectional view illustrating a MTJ structure including a protection layer in accordance with example embodiments.

FIGS. 2 to 4 are cross-sectional views illustrating steps of a method of manufacturing a MTJ structure including a protection layer in accordance with example embodiments.

FIGS. 5 to 7 are perspective views illustrating an apparatus to form a protection layer in accordance with example embodiments.

FIGS. 8 to 61 are cross-sectional views and plan views illustrating steps of a method of manufacturing an MRAM device including a MTJ structure and a protection layer in accordance with example embodiments.

FIGS. 62 and 63 are block diagrams schematically illustrating electronic devices including a semiconductor device according to example embodiments of the inventive concept.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating an MTJ structure including a protection layer in accordance with example embodiments.

Referring to FIG. 1, a protection layer 432 including a fluorinated metal oxide may be formed on a sidewall of a MTJ structure 430. A lower electrode 390 may be formed beneath the MTJ structure 430, and an upper electrode 440 may be formed on the MTJ structure 430. The protection layer 432 may also be formed on sidewalls of the lower and upper electrodes 390 and 440.

In example embodiments, the MTJ structure 430 may include a fixed layer pattern 400, a tunnel barrier layer pattern 410 and a free layer pattern 420 sequentially stacked on the lower electrode 390.

In example embodiments, the fixed layer pattern 400 may include a pinning layer pattern, a lower ferromagnetic layer pattern, an anti-ferromagnetic coupling spacer layer pattern and an upper ferromagnetic layer pattern.

The pinning layer pattern may include, e.g., FeMn, IrMn, PtMn, MnO, MnS, MnTe, MnF₂, FeF₂, FeCl₂, FeO, CoC1₂, CoO, NiCl₂, NiO, Cr, etc. The lower and upper ferromagnetic layer patterns may include, for example, Fe, Ni, and/or Co. The anti-ferromagnetic coupling spacer layer pattern may include, for example, Ru, Ir, and/or Rh.

The tunnel barrier layer pattern may include, e.g., aluminum oxide or magnesium oxide.

The free layer pattern may include, for example, Fe, Ni, and/or Co. In example embodiments, the free layer pattern may include substantially no oxygen. The MTJ structure 430 including the free layer pattern may have a high tunneling magneto resistance (TMR).

The MTJ structure 430 may not be limited to the above composition but may have various compositions.

The protection layer 432 may cover the MTJ structure 430 to substantially prevent the MTJ structure 430 from being damaged in subsequent processes for manufacturing an MRAM device.

For example, the protection layer 432 may include a fluorinated metal oxide such as aluminum oxide including fluorine. When the protection layer 432 includes a fluorinated metal oxide, the protection layer 432 may have electrically insulating property, and the MTJ structure 430 covered by the protection layer 432 may not be substantially oxidized. These may be explained in detail when the process for forming the protection layer 432 is illustrated later.

The lower electrode 390, the MTJ structure 430 and an upper electrode 440 covered by the protection layer 432 may be formed on a pad 365 on a substrate (not illustrated).

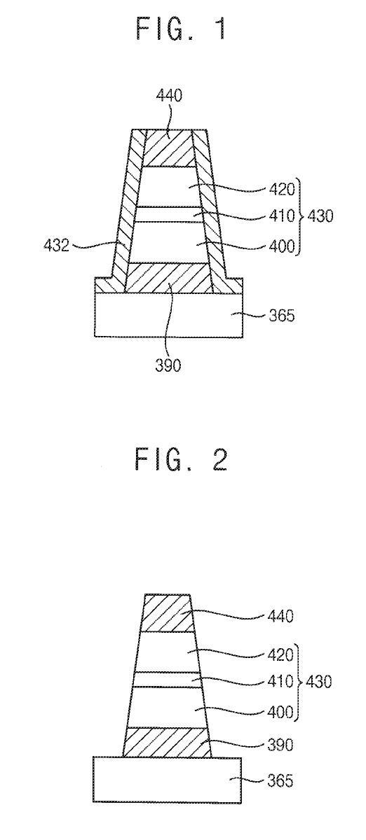

FIGS. 2 to 4 are cross-sectional views illustrating various stages of a method of manufacturing an MTJ structure including a protection layer in accordance with example embodiments. FIGS. 5 to 7 are perspective views illustrating an apparatus for forming the protection layer in accordance with example embodiments.

Referring to FIG. 2, a lower electrode 390, an MTJ structure 430 and an upper electrode 440 may be sequentially stacked on a pad 365 on a substrate (not illustrated).

Particularly, a lower electrode layer, a fixed layer, a tunnel barrier layer, a free layer and an upper electrode layer may be sequentially formed on the pad 365, and the upper electrode layer may be patterned by a photolithography process to form the upper electrode 440. By a dry etch process using the upper electrode 440 as an etching mask, the free layer, the tunnel barrier layer, the fixed layer and the lower electrode layer may be patterned to from the lower electrode 390, the fixed layer pattern 400, the tunnel barrier layer pattern 410 and the free layer pattern 420 sequentially stacked on the pad 365.

The lower and upper electrode layers may be formed to include a conductive material such as a metal and/or a metal nitride.

A barrier layer (not shown) may be additionally formed on the lower electrode layer to prevent a metal of the fixed layer from growing abnormally. The barrier layer may be formed to include an amorphous metal or a metal nitride, e.g., tantalum, tantalum nitride, titanium, titanium nitride, etc.

In example embodiments, the fixed layer may include a pinning layer, a lower ferromagnetic layer, an anti-ferromagnetic coupling spacer layer and an upper ferromagnetic layer.

The pinning layer may be formed to include, for example, FeMn, IrMn, PtMn, MnO, MnS, MnTe, MnF₂, FeF₂, FeCl₂, FeO, CoC1₂, CoO, NiCl₂, NiO, Cr and so on. The lower and upper ferromagnetic layers may be formed to include, for example, Fe, Ni, Co and so on. The anti-ferromagnetic coupling spacer layer may be formed to include, for example, Ru, Ir, Rh and so on.

The tunnel barrier layer may be formed to include, for example, aluminum oxide or magnesium oxide.

The free layer may be formed to include, for example, Fe, Ni, Co and so on.

The dry etching process using the upper electrode 440 as an etching mask may include, for example, a plasma reaction etching process or a sputtering process. The plasma reaction etching process may be performed using an etching gas including a fluorine-containing gas and ammonia gas, and a reaction gas including oxygen for reducing the consumption of the upper electrode 440.

The process for forming the MTJ structure 430 may not be limited to the above description.

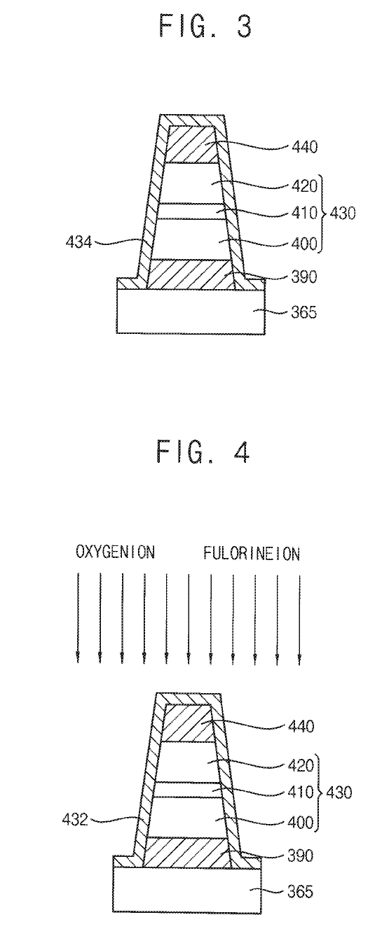

Referring to FIG. 3, a metal layer 434 may be formed on the pad 365 to cover the lower electrode 390, the MTJ structure 430 and the upper electrode 440. The metal layer 434 may be formed on sidewalls of the lower electrode 390 and the MTJ structure 430, on a sidewall and a top surface of the upper electrode 440, and on the pad 365. In example embodiments, the metal layer 434 may include aluminum.

The metal layer 434 may be formed by a chemical vapor deposition (CVD) process, a plasma enhanced chemical vapor deposition (PECVD) process, an atomic layer deposition (ALD) process, etc.

Referring to FIG. 4, the metal layer 434 may be oxidized and fluorinated to form a protection layer 432. Thus, the protection layer 432 may be formed to include a fluorinated metal oxide.

The oxidation and fluorination process may be performed by using oxygen plasma and a fluorine source, respectively.

Hereinafter, the oxidation and fluorination process may be explained in detail with reference to FIGS. 5 to 7.

Referring to FIG. 5, the apparatus may include a plasma generator 500, a chamber 510, a stage 520 and a fluorine source 530.

The plasma generator 500 may be disposed on the chamber 510 to generate oxygen plasma, and the generated oxygen plasma may be supplied into the chamber 510. A RF (radio frequency) power may be supplied to the plasma generator 500 to form plasma, and the plasma generator 500 may generate capacitively coupled plasma or inductively coupled plasma.

The stage 520 may be disposed in the chamber 510, or may be loaded into the chamber 510 before the oxidation and fluorination process. The substrate on which the MTJ structure 430 is formed may be mounted on the stage 520. In example embodiments, the stage 520 may further include an ion accelerator member (not illustrated) to accelerate oxygen ions generated by the plasma generator 500 or fluorine ions supplied by the fluorine source 530.

In example embodiments, the fluorine source 530 may include polytetrafluoroethylene. The fluorine source 530 may have a hollow cylindrical shape.

When the oxygen ions of the oxygen plasma generated by the plasma generator 500 sputter a sidewall of the fluorine source 530, a gas including fluorocarbon (CₓF_{y}) may be generated, and the gas may include fluorine ions.

By the oxygen ions generated by the plasma generator 500 and the fluorine ions supplied by the fluorine source 530, the metal layer 434 may be oxidized and fluorinated to form the protection layer 432 in the chamber 510.

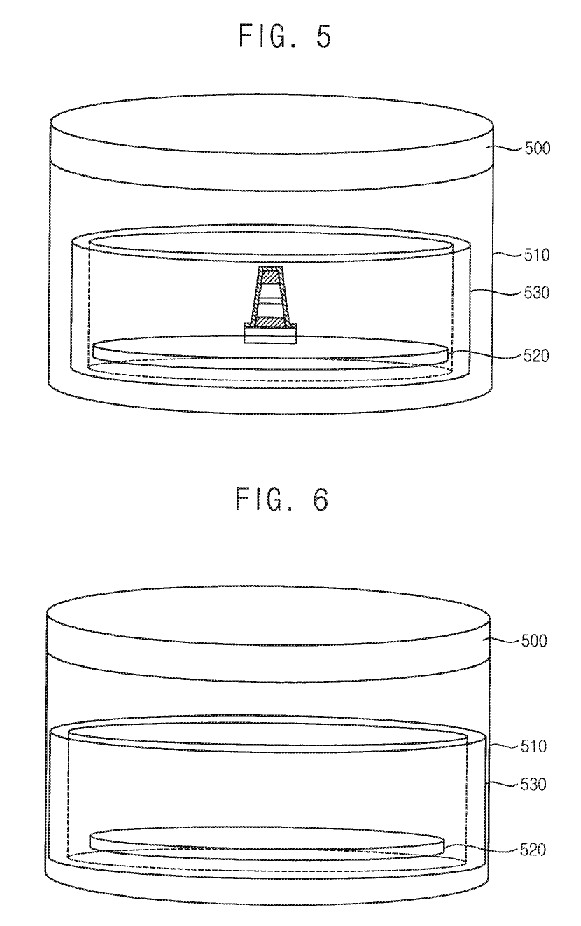

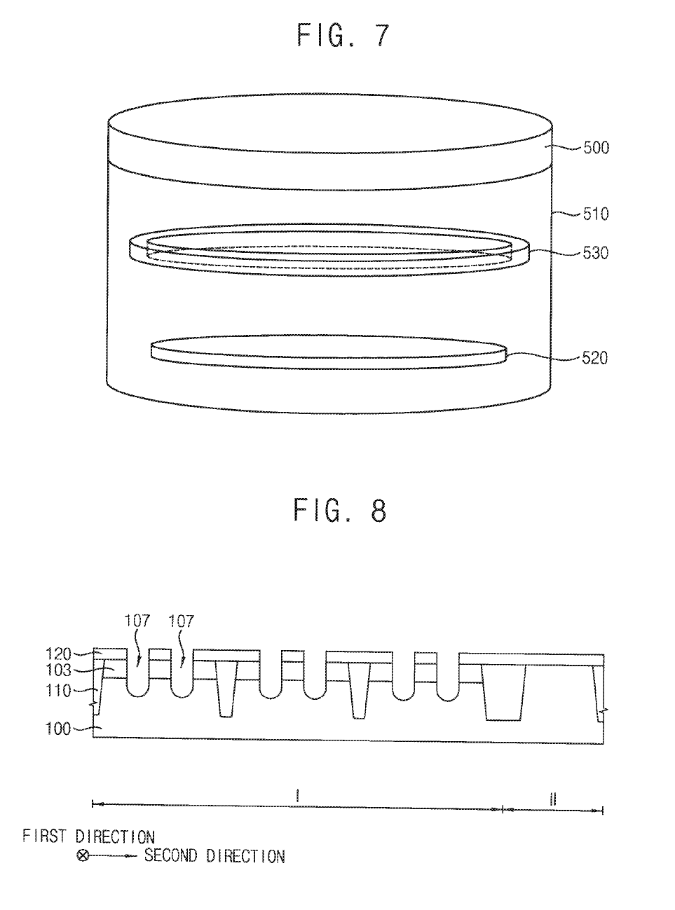

A shape, a width and an arrangement of the fluorine source 530 may be changed to control a fluorination level by the fluorine ions, which may be explained with reference to FIGS. 6 and 7.

Referring to FIG. 6, the fluorine source 530 may be disposed on an inner wall of the chamber 530. Therefore, an internal diameter of the chamber 530 and an external diameter of the fluorine source 530 may be substantially the same.

The fluorine source 530 may cover the inner wall of the chamber 530 to prevent the inner wall of the chamber 530 from being coated with a fluorine-containing layer. If the inner wall of the chamber 530 is coated with a fluorine-containing layer, it may be difficult to control the fluorination level because the coated inner wall of the chamber 530 may serve as another fluorine source.

Referring to FIG. 7, a height of a fluorine source 530 may be smaller than a height of the fluorine source 530 in FIG. 5. An amount of fluorine ions supplied by the fluorine source 530 in FIG. 7 may be smaller than an amount of the fluorine ions supplied by the fluorine source 530 in FIG. 5.

As the metal layer 434 is oxidized, the protection layer 432 may have an insulating property, and electrical short between the fixed layer pattern 400 and the free layer pattern 420 may be prevented. The fluorination process may prevent from oxidation of the free layer pattern 420 in the MTJ structure 430 covered by the metal layer 434 in the oxidation process. The free layer pattern 420 may include substantially no oxygen, and the MTJ structure 420 may have a high TMR.

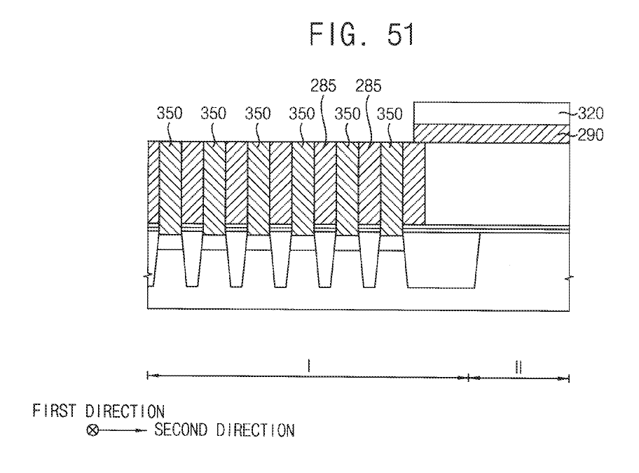

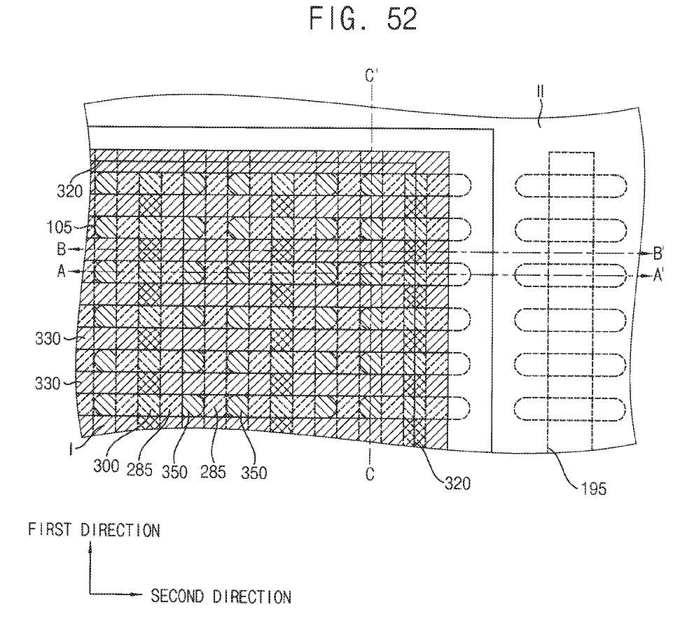

FIGS. 8 to 61 are cross-sectional views and plan views illustrating stages of a method of manufacturing an MRAM device including an MTJ structure and a protection layer in accordance with example embodiments.

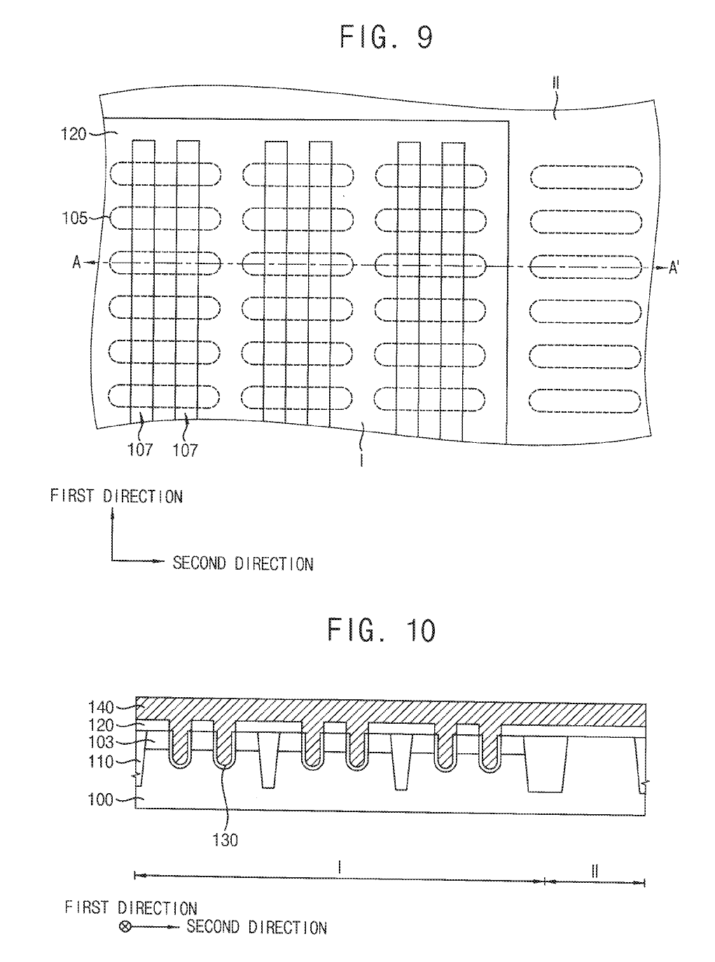

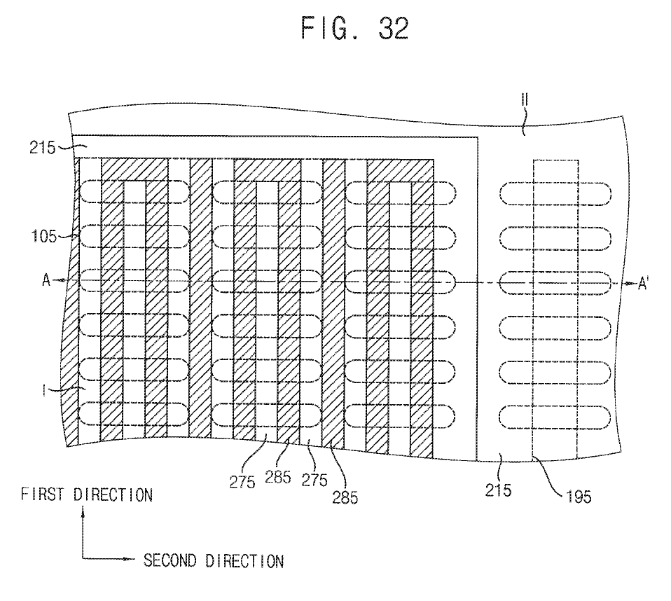

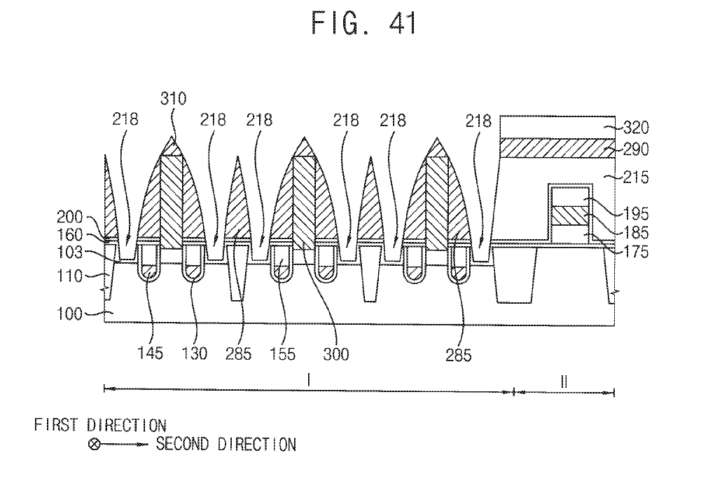

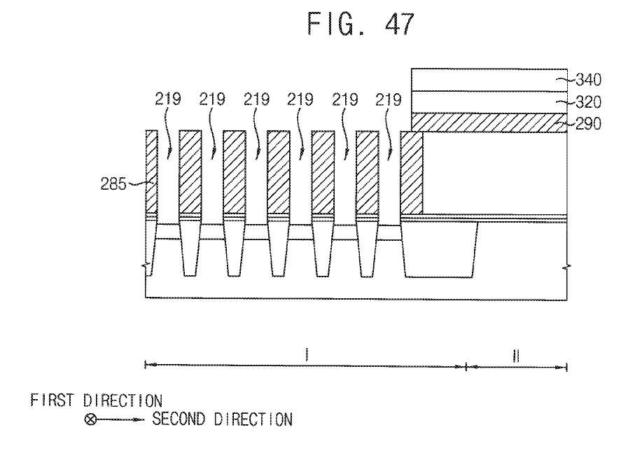

Particularly, FIGS. 8, 10, 11, 13, 15, 16, 18, 19, 21, 22, 24, 26, 28, 30, 31, 33, 35, 37, 39, 41, 43, 45, 46, 47, 49, 50, 51, 53, 54, 56, 58, 60 and 61 are vertical cross-sectional views of the MRAM device, FIGS. 32 and 38 are horizontal cross-sectional views of the MRAM device, and FIGS. 9, 12, 14, 17, 20, 23, 25, 27, 29, 34, 36, 40, 42, 44, 48, 52, 55, 57 and 59 are plan views of the MRAM device. FIGS. 8, 10, 11, 13, 15, 16, 18, 19, 21, 22, 24, 26, 28, 30, 31, 33, 35, 37, 39, 45, 49, 53, 54, 56, 58, 60 and 61 are vertical cross-sectional views cut along a line A-A′, FIGS. 41, 43, 46 and 50 are vertical cross-sectional views cut along a line B-B′, FIGS. 47 and 51 are vertical cross-sectional views cut along a line C-C′, FIG. 32 is a vertical cross-sectional view cut along a line D-D′, and FIG. 38 is a horizontal cross-sectional view cut along a line E-E′.

Referring to FIGS. 8 and 9, impurities may be implanted into an upper portion of a substrate 100 in a first region I to form an impurity region 103, and an isolation layer 110 may be formed on the substrate 100 to divide the substrate 100 into an active region 105 and a field region.

The substrate 100 may be a silicon substrate, a germanium substrate, a silicon-germanium substrate, a silicon-on-insulator substrate, a germanium-on-insulator (GOI) substrate, etc. The substrate 100 may include the first region I in which memory cells may be formed and a second region II in which peripheral circuits may be formed.

The impurities may include n-type impurities, e.g., phosphorous, arsenic, etc., or p-type impurities, for example, boron, gallium and so on. The impurity region 103 may serve as a source/drain region of the memory cells.

The isolation layer 110 may be formed by a shallow trench isolation (STI) process. Particularly, after forming a first trench (not shown) at an upper portion of the substrate 100, an insulation layer sufficiently filling the first trench may be formed on the substrate 100, and an upper portion of the insulation layer may be planarized until a top surface of the substrate 100 is exposed. The insulation layer may be formed by a chemical vapor deposition (CVD) process, a high density plasma chemical vapor deposition (HDP-CVD) process and so on.

The substrate 100 may be partially removed to form a second trench 107.

In example embodiments, a first mask 120 may be formed on the substrate 100, and an upper portion of the substrate 100 may be etched using the first mask 120 as an etching mask to form the second trench 107. In example embodiments, the second trench 107 may extend in a first direction substantially parallel to a top surface of the substrate 100, and a plurality of second trenches 107 may be formed and arranged in a second direction substantially parallel to the top surface of the substrate 100 and substantially perpendicular to the first direction. In an example embodiment, two second trenches 107 may be formed within each active region 105 divided by the isolation layer 110.

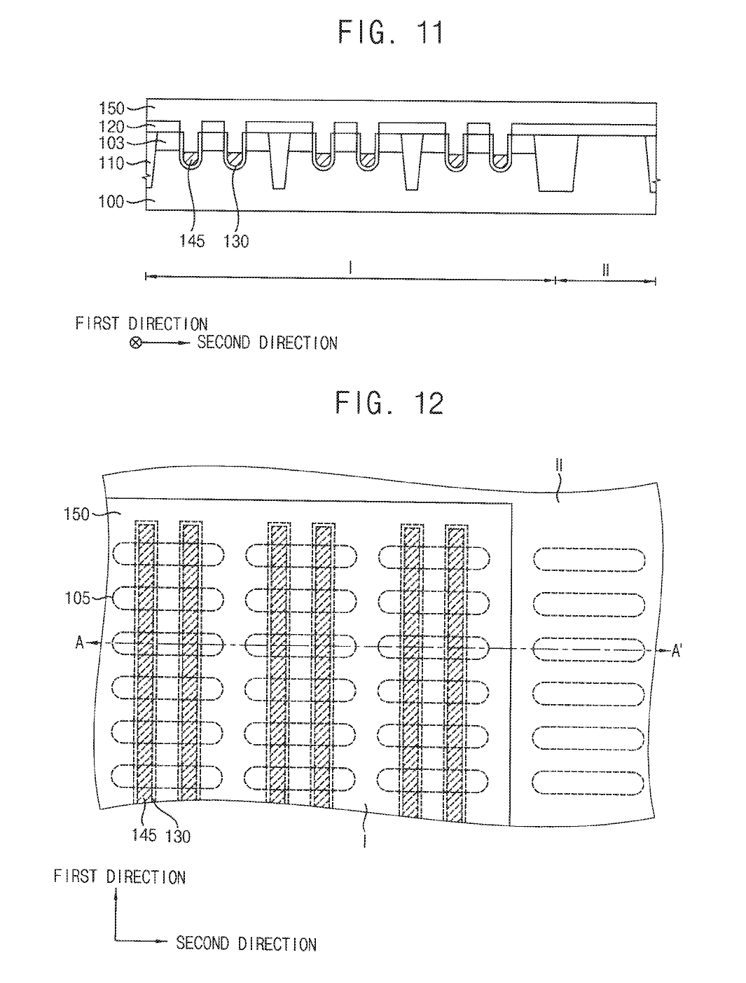

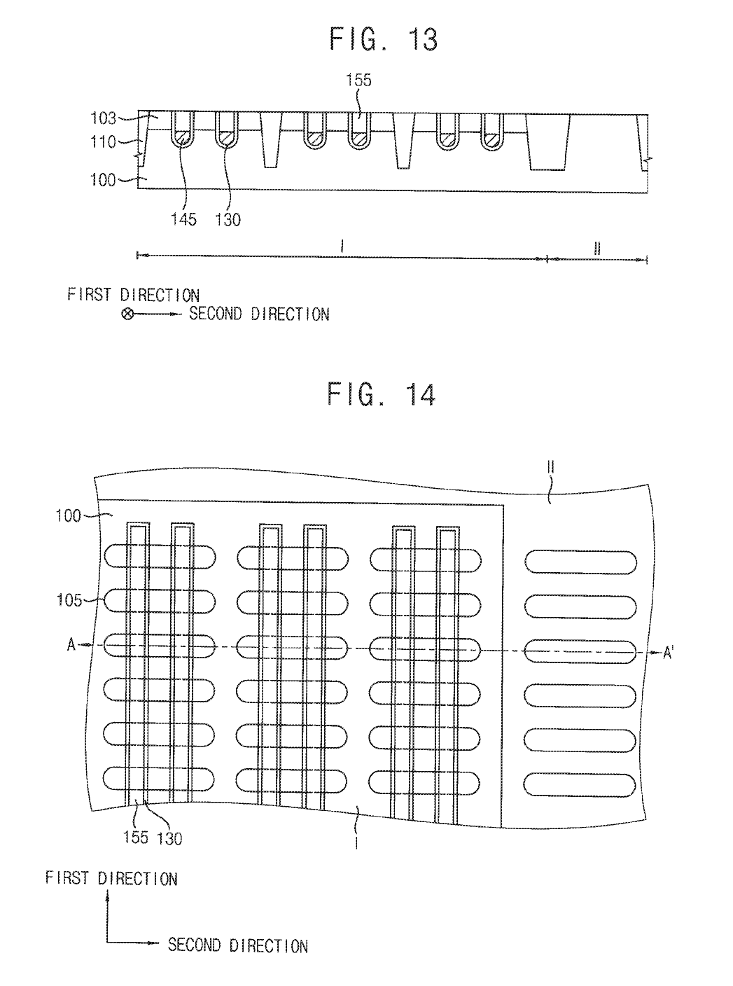

Referring to FIG. 10, a first gate insulation layer 130 may be formed on an inner wall of the second trench 107, and a first gate electrode layer 140 may be formed on the first gate insulation layer 130 and the first mask 120 to sufficiently fill the second trench 107.

In example embodiments, the first gate insulation layer 130 may be formed by a thermal oxidation process or a radical oxidation process on an upper portion of the substrate 100 exposed by the second trench 107.

The first gate electrode layer 140 may include a metal or a metal nitride, for example, tungsten, titanium nitride, tantalum nitride, etc., and/or a metal silicide by an atomic layer deposition (ALD) process, a physical vapor deposition (PVD) process and so on.

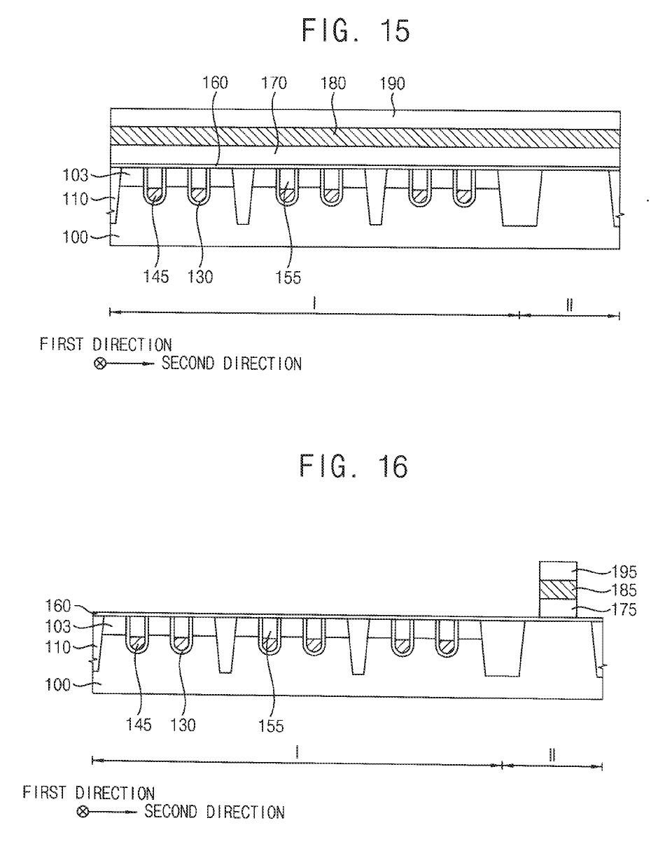

Referring to FIGS. 11 and 12, an upper portion of the first gate electrode layer 140 may be removed to form a first gate electrode 145 partially filling the second trench 107, and a first capping layer 150 filling a remaining portion of the second trench 107 may be formed on the first gate electrode 145, the first gate insulation layer 130 and the first mask 120.

In example embodiments, the first gate electrode 145 may extend in the first direction, and a plurality of first gate electrodes 145 may be arranged in the second direction. The first capping layer 150 may be formed to include, for example, silicon oxide, silicon nitride.

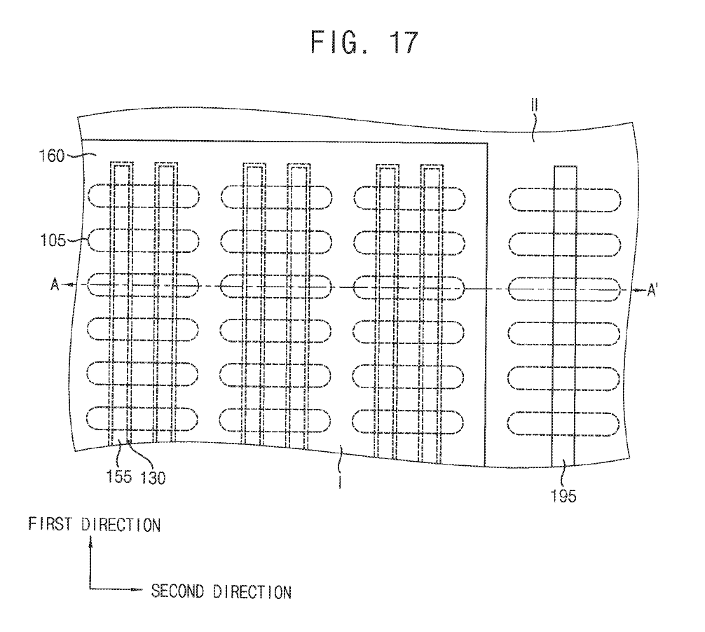

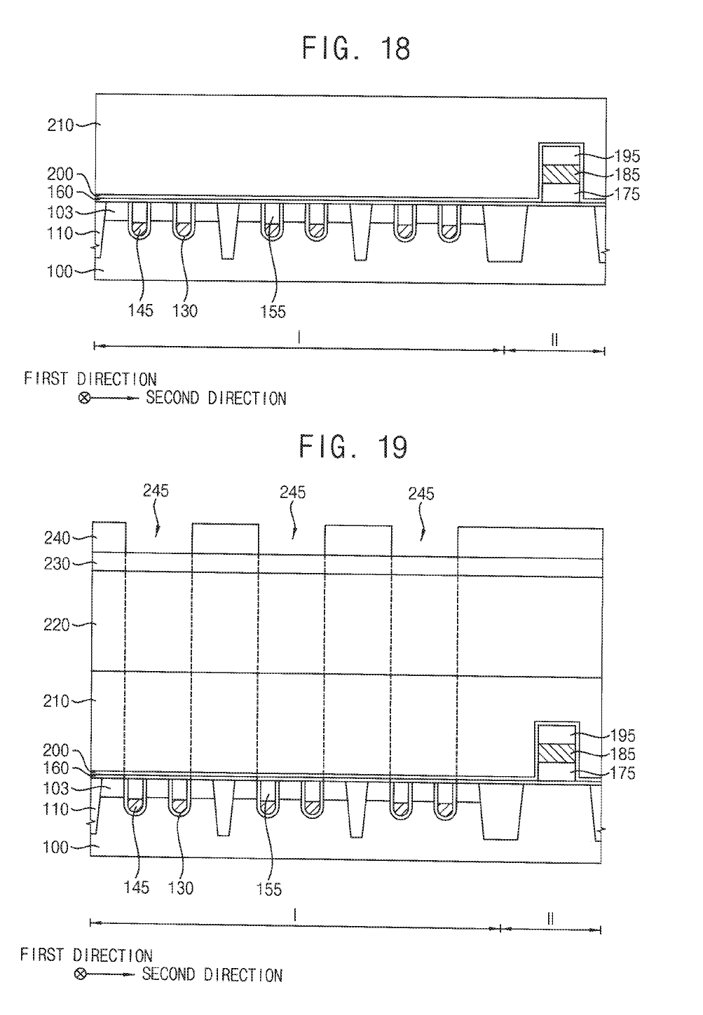

Referring to FIGS. 13 and 14, an upper portion of the first capping layer 150 and the first mask 120 may be removed until a top surface of the substrate 100 may be exposed by a planarization process such as a CMP process and/or an etch back process to form a first capping layer pattern 155. In example embodiments, the first capping layer pattern 155 may extend in the first direction, and a plurality of first capping layer patterns 155 may be arranged in the second direction.

The first gate insulation layer 130, the first gate electrode 145 and the first capping layer pattern 155 may form a first gate structure, and the first gate structure may be a buried gate structure filling the second trench 105. The first gate structure and the impurity region 103 may form a transistor.

Referring to FIG. 15, a second gate insulation layer 160, a second gate electrode layer 170, a third gate electrode layer 180 and a second mask layer 190 may be sequentially formed on the first gate structure, the substrate 100 and the isolation layer 110.

The second gate insulation layer 160 may be formed to include, for example, silicon oxide, the second gate electrode layer 170 may be formed to include, for example, doped polysilicon, the third gate electrode layer 180 may be formed to include, for example, a metal and/or a metal nitride.

Referring to FIGS. 16 and 17, the second mask layer 190 may be patterned by a photolithography process to form a second mask 195 in the second region II, and the third and second gate electrode layers 180 and 170 may be etched using the second mask 195 as an etching mask to form a third gate electrode 185 and a second gate electrode 175, respectively.

The second gate insulation layer 160, the second gate electrode 175, the third gate electrode 185 and the second mask 195 sequentially stacked on the substrate 100 in the second region II may form a second gate structure, and the second and third gate electrodes 175 and 185 and the second mask 195 may be referred to as a second gate electrode structure.

Referring to FIG. 18, an etch stop layer 200 may be formed on the second insulation layer 160 and the second gate electrode structure, and a first insulating interlayer 210 may be formed on the etch stop layer 200 to have a top surface higher than that of the second gate electrode structure so that the first insulating interlayer 210 may sufficiently cover the second gate electrode structure.

The etch stop layer 200 may be formed to include, for example, silicon nitride, and the first insulating interlayer 210 may be formed to include, for example, silicon oxide.

A portion of the first insulating interlayer 210 in the first region I may be removed in subsequent processes, and thus may serve as a sacrificial layer.

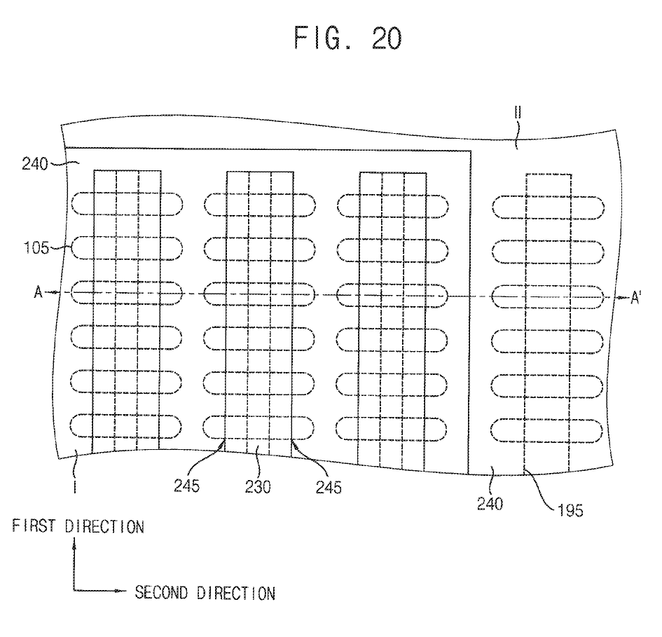

Referring to FIGS. 19 and 20, a silicon-on-hardmask (SOH) layer 220, an oxynitride layer 230 and a first photoresist pattern 240 may be sequentially formed on the first insulating interlayer 210.

The first photoresist pattern 240 may include a plurality of first openings 245, each of which may extend in the first direction, arranged in the second direction. In example embodiments, each first opening 245 may overlap two first gate structures adjacent to each other in each active region 105 and a portion of the substrate 100 therebetween.

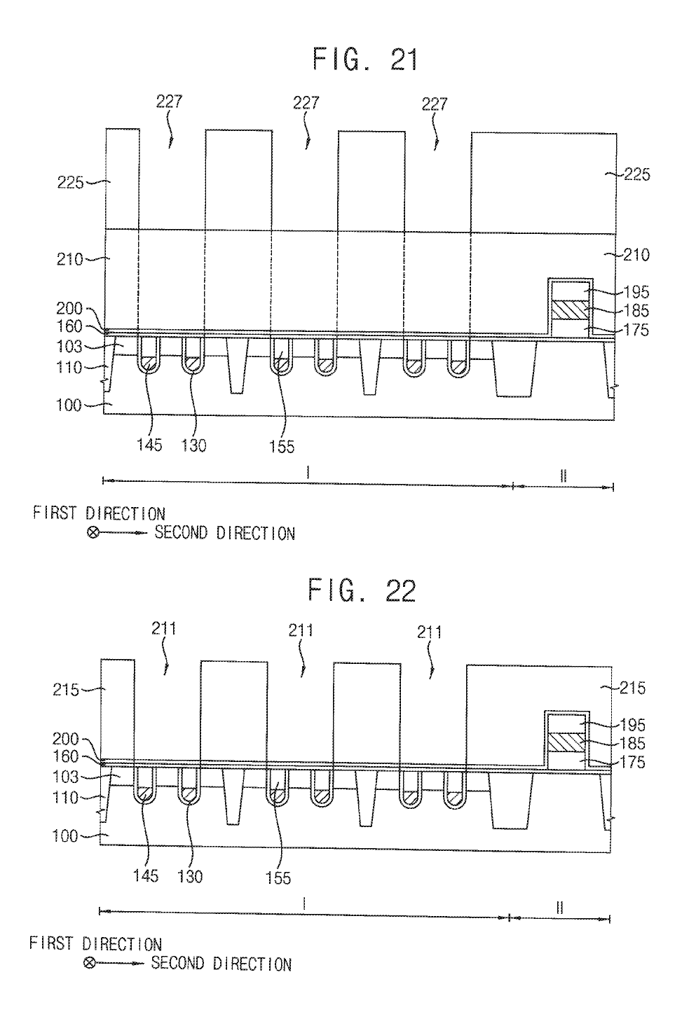

Referring to FIG. 21, the oxynitride layer 230 may be etched using the first photoresist pattern 240 as an etching mask to form an oxynitride layer pattern (not shown), and the SOH layer 220 may be etched using the oxynitride layer pattern as an etching mask to form an SOH layer pattern 225. The SOH layer pattern 225 may include a plurality of second openings 227 exposing portions of top surfaces of the first insulating interlayer 210.

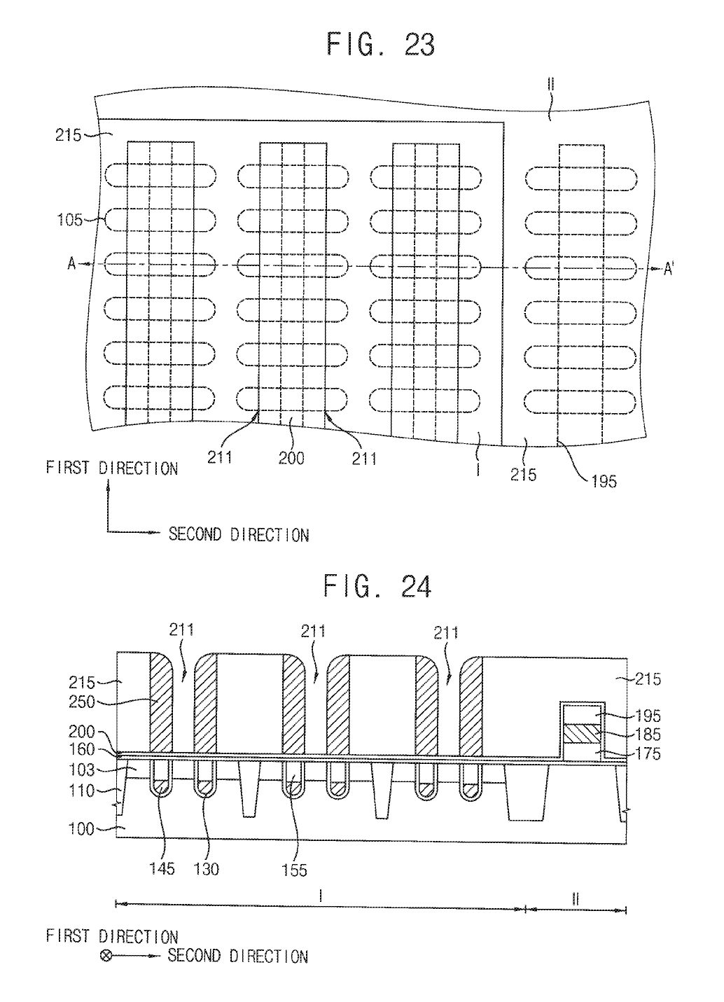

Referring to FIGS. 22 and 23, the first insulating interlayer 210 may be etched using the SOH layer pattern 225 as an etching mask to form a first insulating interlayer pattern 215.

In example embodiments, each third opening 211 may overlap two first gate structures adjacent to each other in each active region 105 and the portion of the substrate 100 therebetween.

As described above, the portion of the first insulating interlayer pattern 215 in the first region I may be removed in a subsequent process, and thus may be referred to as a sacrificial layer pattern 215 hereinafter.

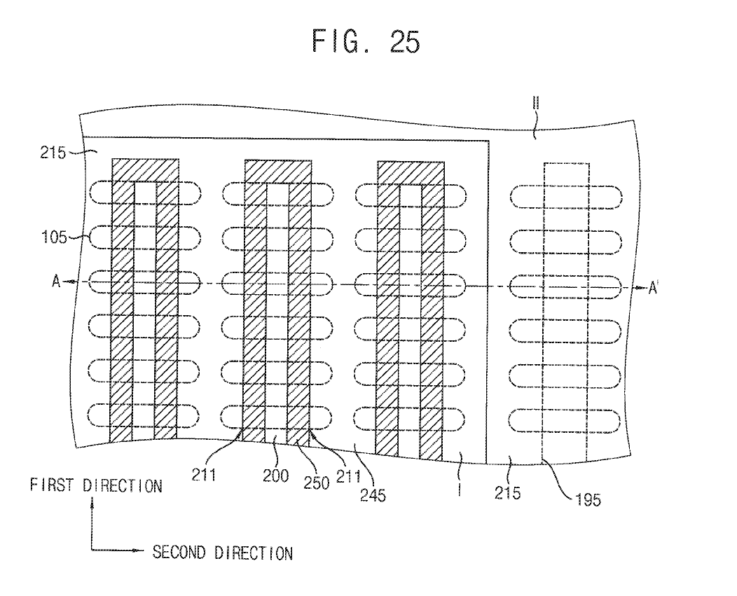

Referring to FIGS. 24 and 25, a first spacer 250 may be formed on a sidewall of each third opening 211.

The first spacers 250 may be formed by forming a first spacer layer on the sidewalls of the third openings 211, the exposed top surfaces of the etch stop layer 200 and the sacrificial layer pattern 215, and anisotropically etching the first spacer layer.

The first spacer layer may be formed to include, for example, silicon nitride. In some embodiments, each first spacer 250 may overlap the first gate structure. Portions of each first spacer 250 opposite to each other in each third opening 211 may be spaced apart from each other by a first distance in the second direction. In an example embodiment, the first distance may be similar to the width of the first gate structure in the second direction.

In plan view, one first spacer 250 of a loop shape may be formed in each third opening 211. That is, each first spacer 250 may have first two portions each of which may extend in the first direction, and second two portions connecting the first two portions adjacent to each other. Hereinafter, the first two portions of the first spacer 250 may be simply referred to as independent first spacers 250 for the convenience of explanation. Thus, the first spacers 250 in each third opening 211 may be spaced apart from each other by the first distance in the second direction.

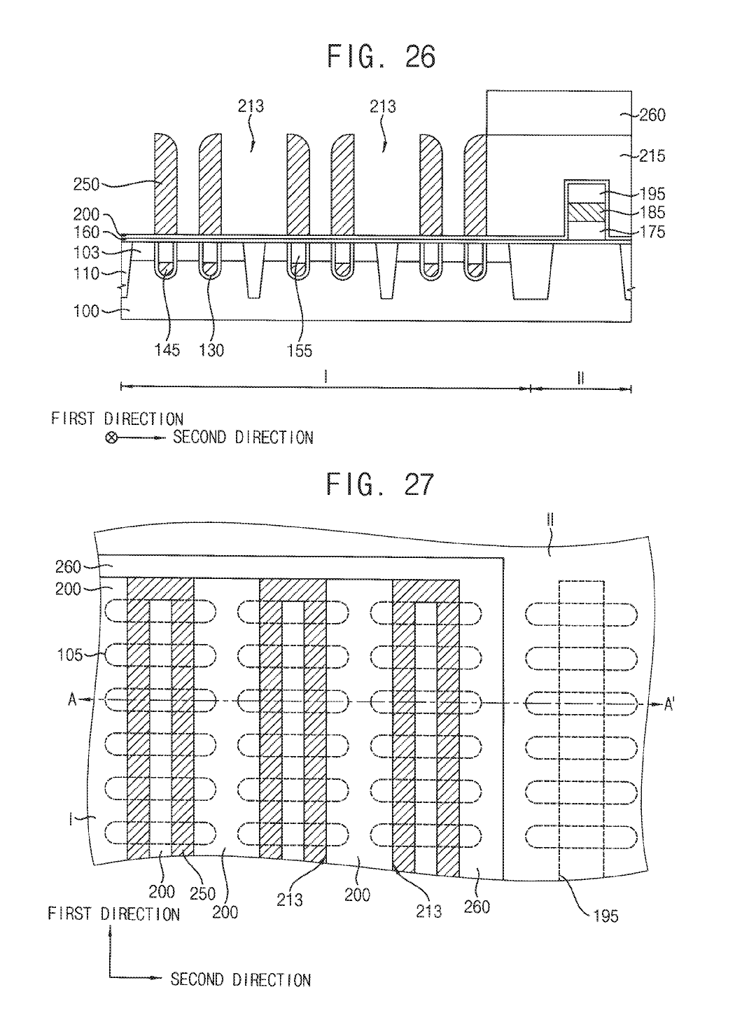

Referring to FIGS. 26 and 27, a third mask 260 may be formed on the sacrificial layer pattern 215, and a portion of the sacrificial layer pattern 215 not covered by the third mask 260 may be removed to form a plurality of fourth openings 213 exposing top surfaces of the etch stop layer 200.

In example embodiments, the third mask 260 may be formed to cover substantially the entire portion of the sacrificial layer pattern 215 in the second region II and a portion of the sacrificial layer pattern 215 in the first region I adjacent to the second region II, and may expose a central portion of the sacrificial layer pattern 215 in the first region I. In some embodiments, the portion of the sacrificial layer pattern 215 not covered by the third mask 260 may be removed by, for example, a wet etching process using hydrofluoric acid as an etching solution.

As the portion of the sacrificial layer pattern 215 in the first region I is removed, the first spacers 250 may be spaced apart from each other by a second distance, which may correspond to a width of the sacrificial layer pattern 215 in the second direction. That is, the first spacers 250 may be spaced apart from each other by the second distance through the fourth opening 213. In an example embodiment, the second distance may be larger than the first distance. As a result, the first spacers 250 disposed in the second direction may be spaced apart from one another by the first distance or the second distance.

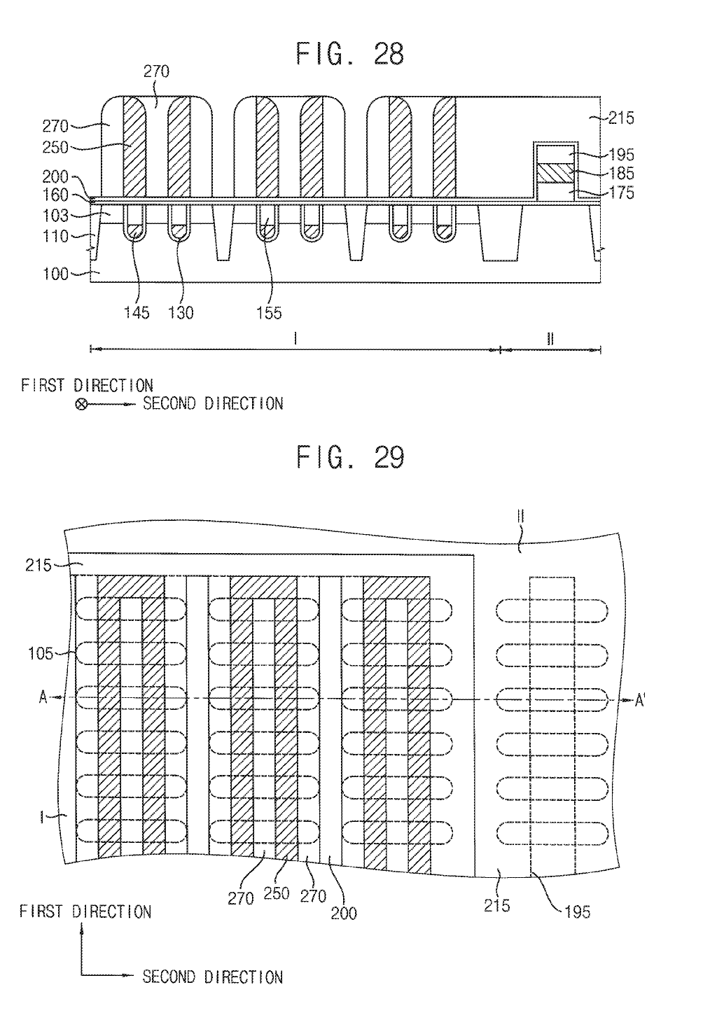

Referring to FIGS. 28 and 29, after removing the third mask 260, second spacers 270 contacting the first spacers 250 may be formed on the substrate 100.

In some embodiments, the second spacers 270 may be formed by forming a second spacer layer covering the first spacers 250 on the etch stop layer 200 and the sacrificial layer pattern 215, and anisotropically etching the second spacer layer.

The second spacer layer may include, for example, silicon oxide, and thus a portion of the second spacer layer contacting the sacrificial layer pattern 215 may be merged thereto. In example embodiments, the second spacer layer may fill spaces between the first spacers 250 spaced apart from each other by the first distance, and may partially fill spaces and partially cover a portion of the etch stop layer 200 between the first spacers 250 spaced apart from each other by the second distance.

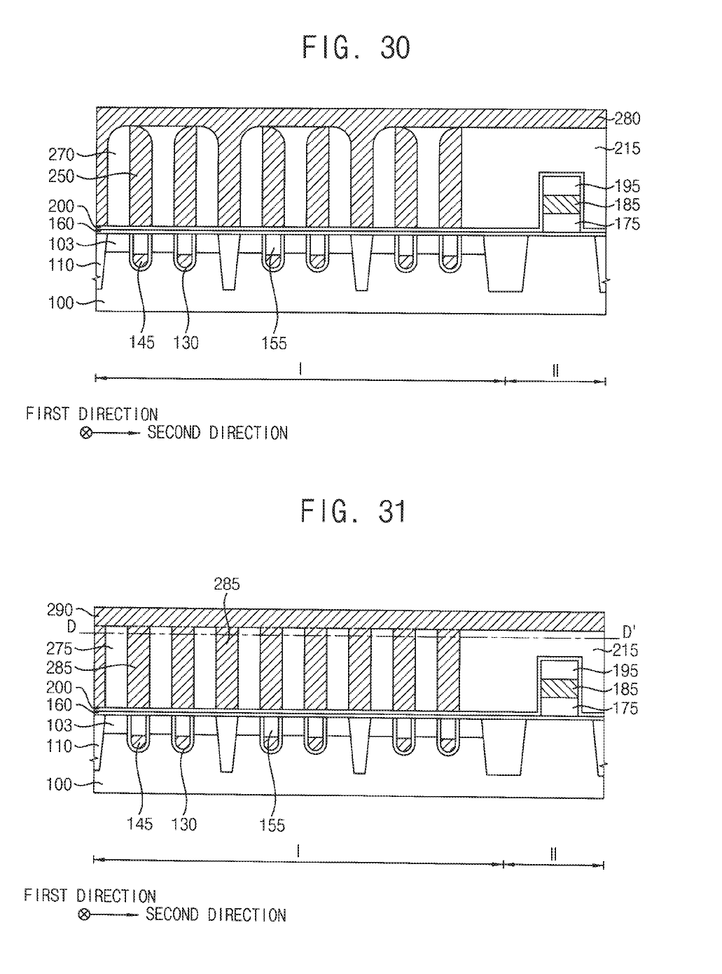

Referring to FIG. 30, a filling layer 280 may be formed on the etch stop layer 200, the first and second spacers 250 and 270 and the sacrificial layer pattern 215 to sufficiently fill the spaces between the second spacers 270, i.e., remaining portions of the fourth openings 213.

In example embodiments, the filling layer 280 may include a material substantially the same as that of the first spacers 250, e.g., silicon nitride.

Referring to FIGS. 31 and 32, upper portions of the filling layer 280, the first and second spacers 250 and 270 and the sacrificial layer pattern 215 may be planarized to form first and second patterns 285 and 275, and a second capping layer 290 may be formed on the first and second patterns 285 and 275 and the sacrificial layer pattern 215.

By performing the planarization process, the first spacers 250 and the filling layer 280 may be converted into the first patterns 285, and the second spacers 270 may be converted into the second patterns 275. Thus, each of the first and second patterns 285 and 275 may extend in the first direction, and the first and second patterns 285 and 275 may be alternately and repeatedly arranged in the second direction. In example embodiments, some of the first patterns 285 may overlap the first gate structure, and the others of the first patterns 285 may overlap the isolation layer 110. In some embodiments, the second patterns 275 may overlap the impurity region 103 adjacent to the first gate structure.

The first patterns 285 may include, for example, silicon nitride, and the second patterns 275 may include, for example, silicon oxide. The second capping layer 290 may be formed to include, for example, silicon nitride, thereby being merged into the first patterns 285.

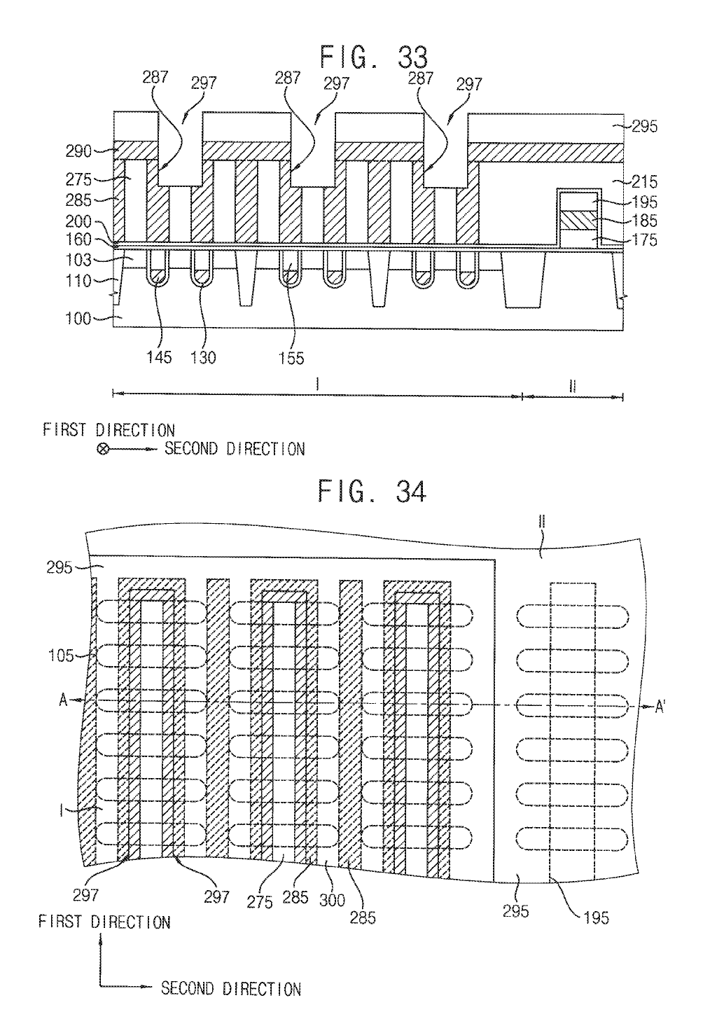

Referring to FIGS. 33 and 34, a second photoresist pattern 295 may be formed on the second capping layer 290, and the second capping layer 290 and upper portions of the first and second patterns 285 and 275 may be etched using the second photoresist pattern 295 as an etching mask to form recesses 287.

In some embodiments, the second photoresist pattern 295 may include a plurality of fifth openings 297, each of which may extend in the first direction, disposed in the second direction. Each fifth opening 297 may overlap the second pattern 275 on a portion of the substrate 100 between the first gate structures adjacent to each other and a portion of the first patterns 285 adjacent to the second pattern 275 in each active region 105. Thus, (3n−2)th second patterns 275, e.g., first, fourth and seventh second patterns 275 may be exposed by the recesses 287 when counted from an outermost one of the second patterns 275. Here, n indicates a positive integer.

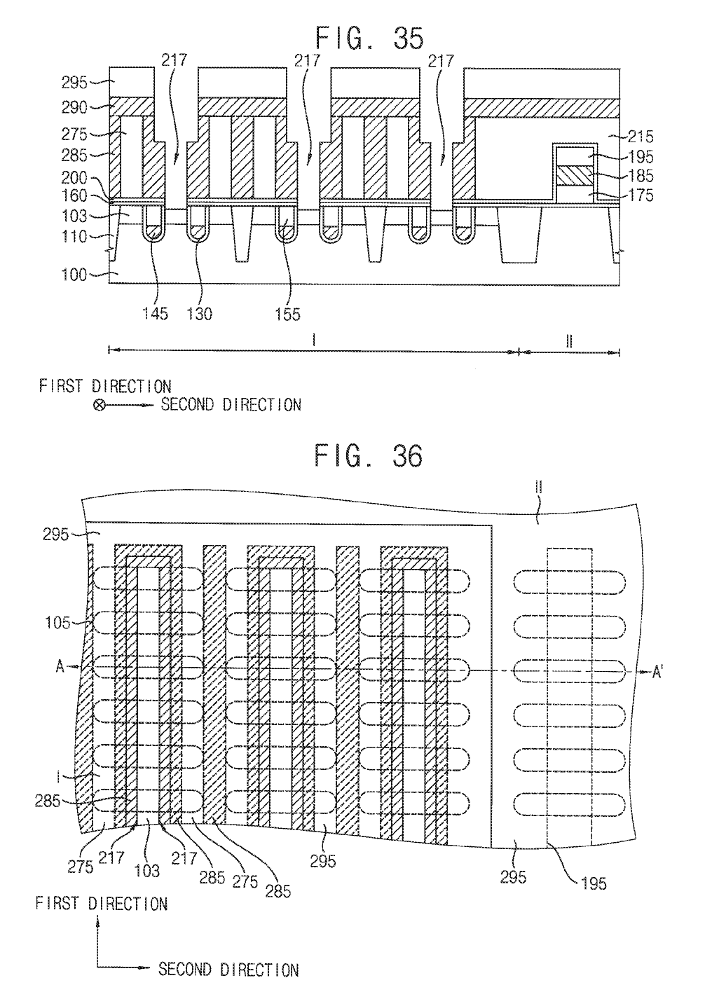

Referring to FIGS. 35 and 36, the second patterns 275 exposed by the recesses 287 may be removed, and portions of the etch stop layer 200 and the second gate insulation layer 160 thereunder may be removed to form sixth openings 217 exposing upper portions of the substrate 100 and being in fluid communication with the recesses 287, respectively. Each sixth opening 217 may be formed to extend in the first direction.

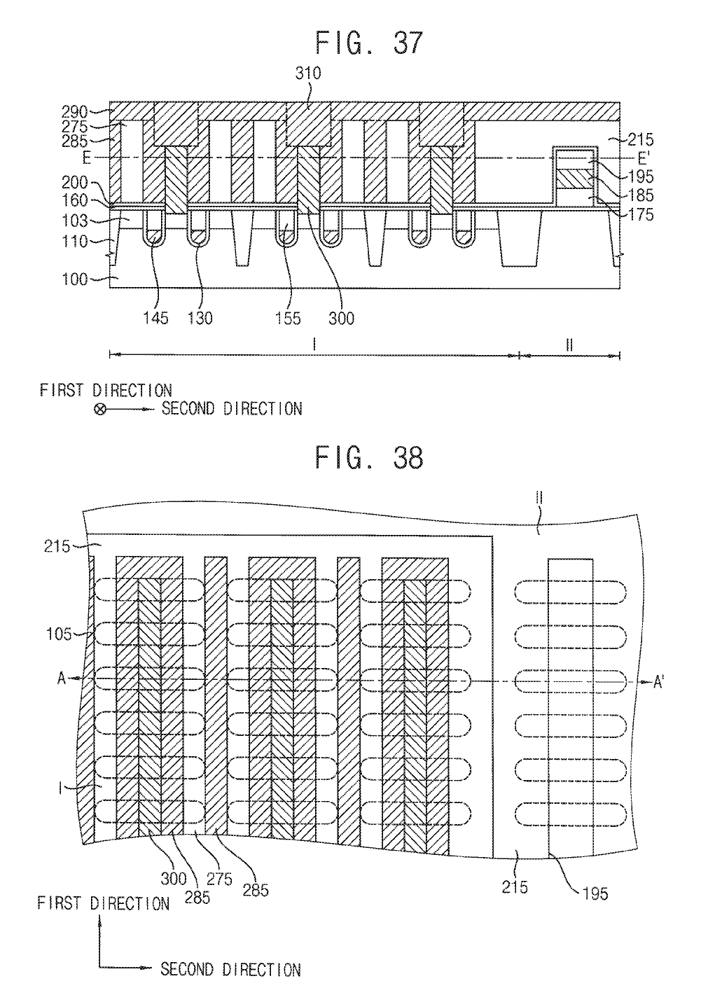

Referring to FIGS. 37 and 38, after removing the second photoresist pattern 295, a source line 300 filling each sixth opening 217 may be formed, and a third capping layer pattern 310 filling each recess 287 may be formed.

The source lines 300 may be formed by forming a first conductive layer on the exposed upper portions of the substrate 100 to fill the sixth openings 217 and the recesses 287, and removing an upper portion of the first conductive layer. In some embodiments, portions of the first conductive layer in the recesses 287 may be removed so that each source line 300 may be formed to fill only each sixth opening 217. The first conductive layer may be formed to include a metal, for example, tungsten, titanium, tantalum, and/or a metal nitride, for example, tungsten nitride, titanium nitride, tantalum nitride.

Each source line 300 may extend in the first direction, and a plurality of source lines 300 may be arranged in the second direction. In some embodiments, each source line 300 may be formed on portions of the substrate 100 and the isolation layer 110 between neighboring first gate structures.

The third capping layer may include, for example, silicon nitride, thereby being merged into the first patterns 285 and/or the second capping layer 290.

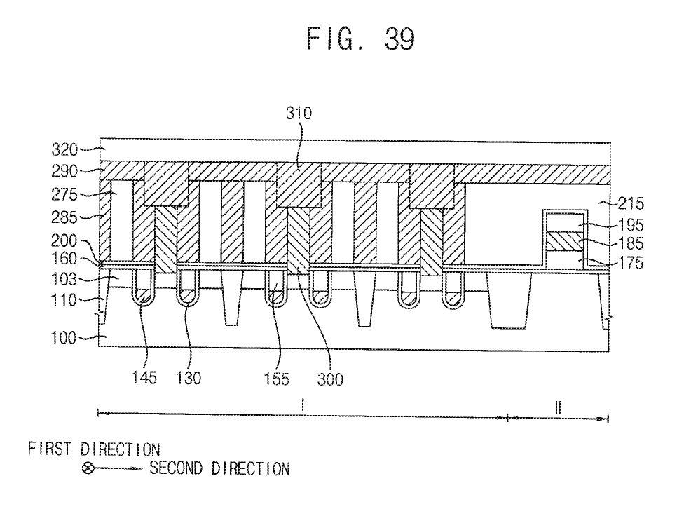

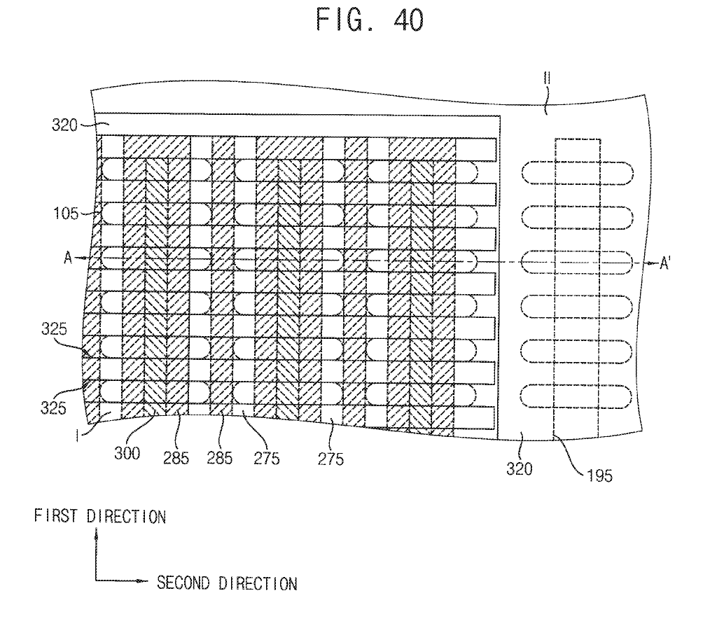

Referring to FIGS. 39 and 40, a fourth mask 320 may be formed on the second capping layer 290, the third capping layer pattern 310 and the sacrificial layer pattern 215.

In example embodiments, the fourth mask 320 may include a plurality of eighth openings 325, each of which may extend in the second direction, arranged in the first direction. Each eighth opening 325 may be formed in the first region I, and may partially expose the second capping layer 290, the third capping layer pattern 310 and the sacrificial layer pattern 215. In some embodiments, each eighth opening 325 may overlap the field region of the substrate 100, i.e., overlap the isolation layer 110.

The fourth mask 320 may include a material having an etching selectivity with respect to both of silicon nitride and silicon oxide, for example, polysilicon.

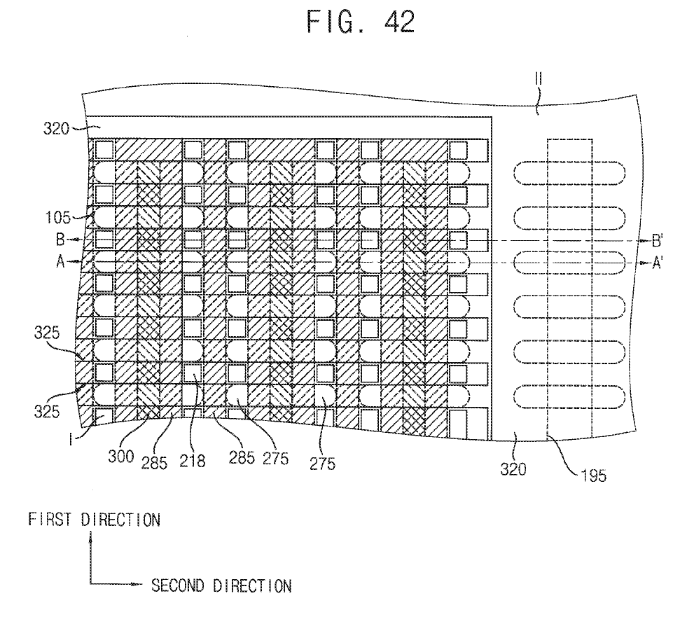

Referring to FIGS. 41 and 42, the second capping layer 290 and the second patterns 275 may be etched using the fourth mask 320 as an etching mask.

In some embodiments, the etching process may be performed by a dry etching process. When the dry etching process is performed, portions of the first patterns 285 and the third capping layer pattern 310 adjacent to the second patterns 275 may be removed, however, the source lines 300 may be protected by the third capping layer pattern 310, without being removed.

During the dry etching process, portions of the etch stop layer 200, the second gate insulation layer 160 and the substrate 100 under the second patterns 275 may also be removed to form ninth openings 218 exposing upper portions of the substrate 100.

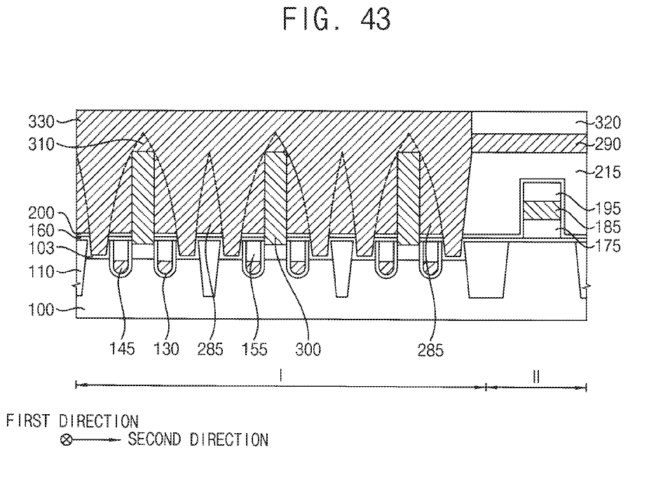

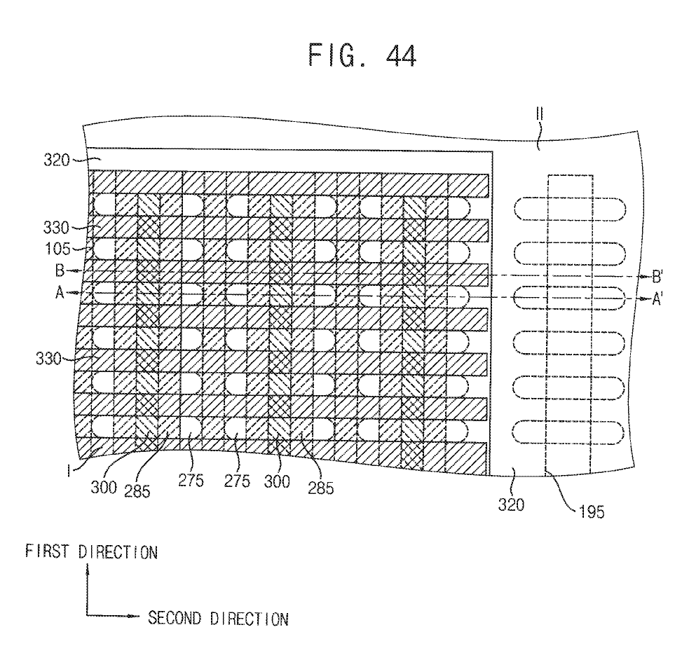

Referring to FIGS. 43 and 44, third patterns 330 filling the ninth openings 218 may be formed.

The third patterns 330 may be formed by forming a first insulation layer on the substrate 100, the first patterns 285, the third capping layer pattern 310 and the fourth mask 320 to sufficiently fill the ninth openings 218, and planarizing an upper portion of the first insulation layer. In an example embodiment, the planarization process may be performed until an upper portion of the fourth mask 320 may be removed. The first insulation layer may be formed to include, for example, silicon nitride, thereby being merged into the first patterns 285, the third capping layer pattern 310 and the second capping layer 290.

In example embodiments, each third pattern 330 may extend in the second direction, and a plurality of third patterns 330 may be arranged in the first direction.

Thus, sidewalls of the second patterns 275 may be surrounded by the first and third patterns 285 and 330.

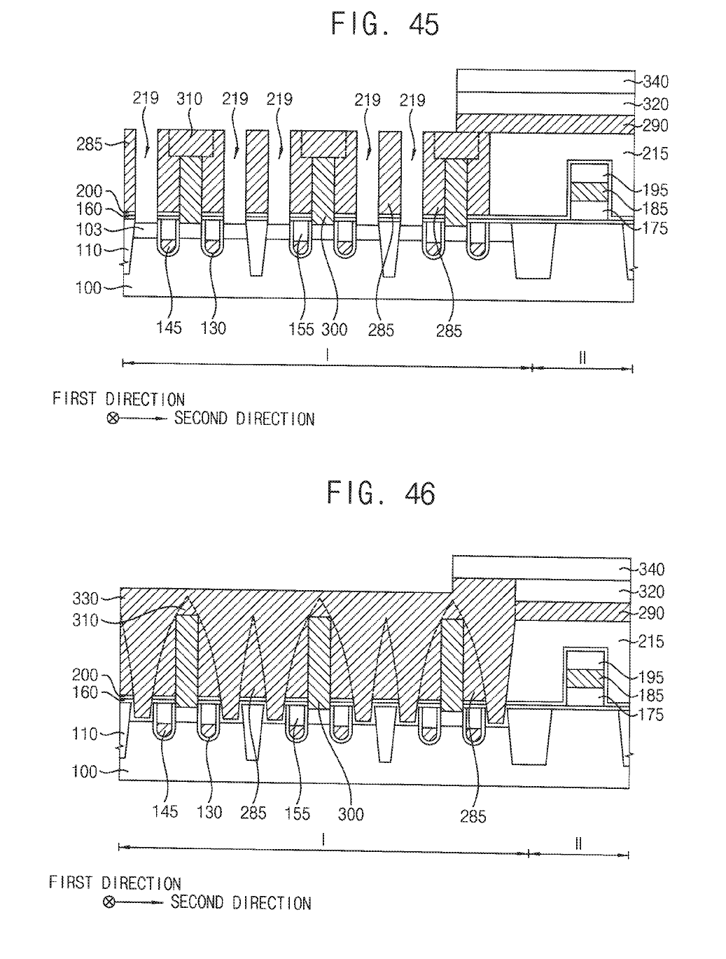

Referring to FIGS. 45 to 48, after a third photoresist pattern 340 is formed on the second capping layer 290, the third patterns 330 and the fourth mask 320, the second capping layer 290, the third patterns 330, the third capping layer pattern 310 and the fourth mask 320 may be etched using the third photoresist pattern 340 as an etching mask to expose the second patterns 275.

The third photoresist pattern 340 may cover the second region II and a portion of the first region I adjacent thereto. Thus, the sacrificial layer pattern 215 in the second region II may be protected during the etching process.

The second patterns 275 of which sidewalls may be surrounded by the first and third patterns 285 and 330 in the first region I may be exposed by performing a dry etching process using the third photoresist pattern 340 as an etching mask. During the dry etching process, an upper portion of the third capping layer pattern 310 may be removed so that a top surface of the third capping layer pattern 310 may be substantially coplanar with top surfaces of the first, second and third patterns 285, 275 and 330.

The exposed second patterns 275 and portions of the etch stop layer 200 and the second gate insulation layer 160 thereunder may be removed to form tenth openings 219 exposing upper portions of the substrate 100.

In some embodiments, the exposed second patterns 275 may be removed by a wet etching process, using hydrofluoric acid as an etching solution, and the portions of the etch stop layer 200 and the second gate insulation layer 160 may be removed by a dry etching process.

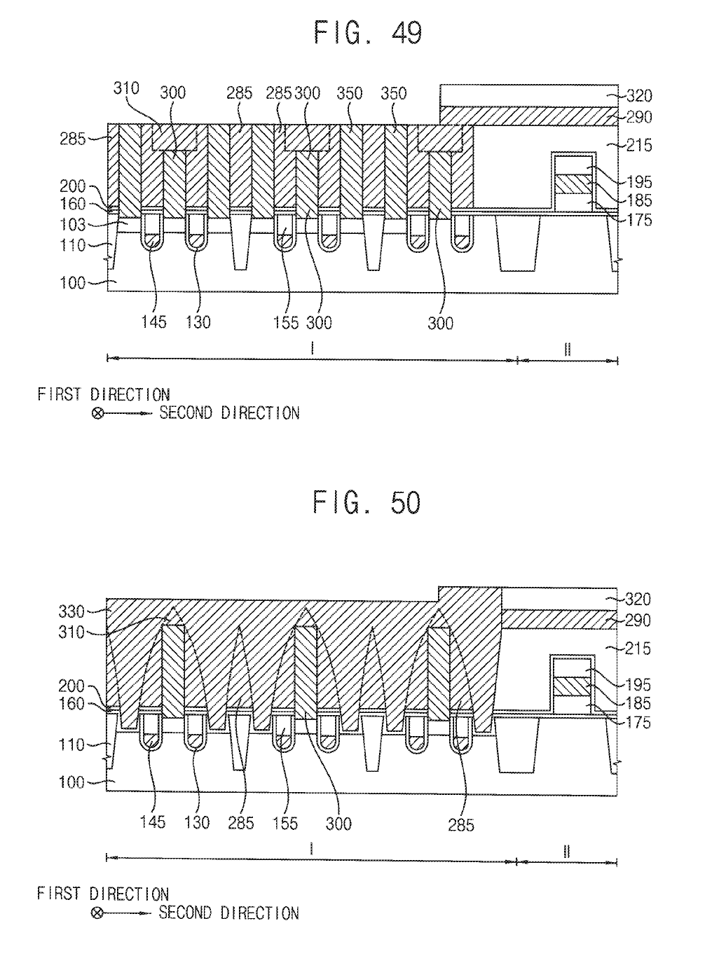

Referring to FIGS. 49 to 52, a contact plug 350 filling each tenth opening 219 may be formed.

The contact plugs 350 may be formed by forming a second conductive layer on the substrate 100, the first and third patterns 285 and 330, the third capping layer pattern 310 and the fourth mask 320, and planarizing an upper portion of the second conductive layer. In example embodiments, a top surface of the contact plugs 350 may be formed to be substantially coplanar with the top surfaces of the first and third patterns 285 and 330 and the third capping layer pattern 310.

The second conductive layer may be formed to include a metal, for example, tungsten, titanium, tantalum, and/or a metal nitride, for example, tungsten nitride, titanium nitride, tantalum nitride.

The contact plugs 350 may be formed both in the first and second directions, and each contact plug 350 may contact the impurity region 103 of the substrate 100. In example embodiments, two contact plugs 350 may be formed in the second direction between two source lines 300.

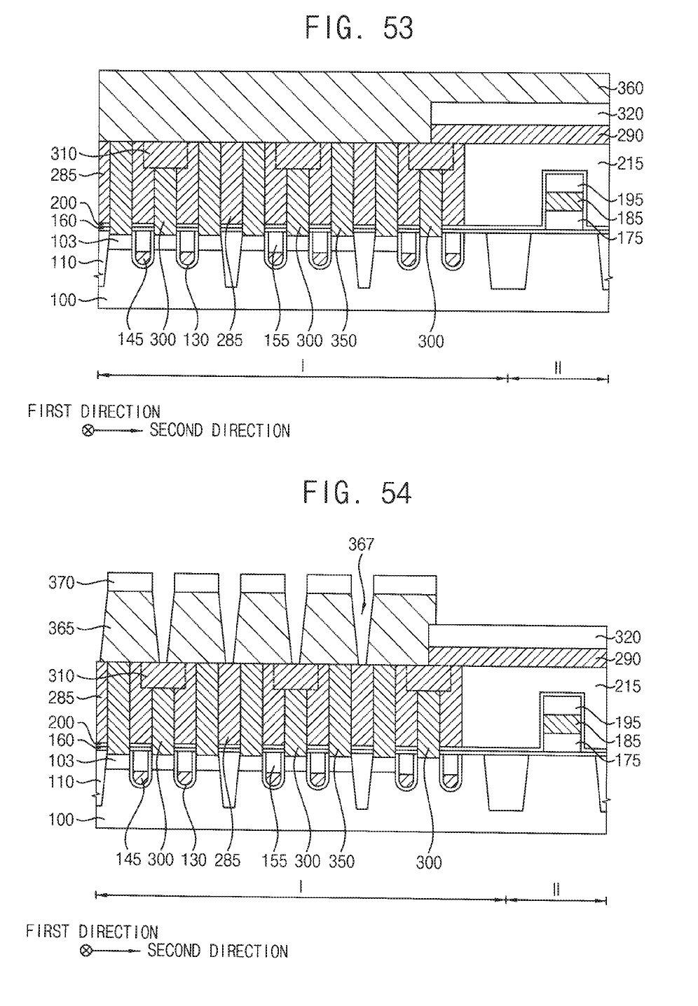

Referring to FIG. 53, a pad layer 360 may be formed on the first and third patterns 285 and 330, the third capping layer pattern 310, the contact plugs 350 and the fourth mask 320.

The pad layer 360 may include a metal, for example, tungsten, titanium, tantalum, and/or a metal nitride, for example, tungsten nitride, titanium nitride, tantalum nitride.

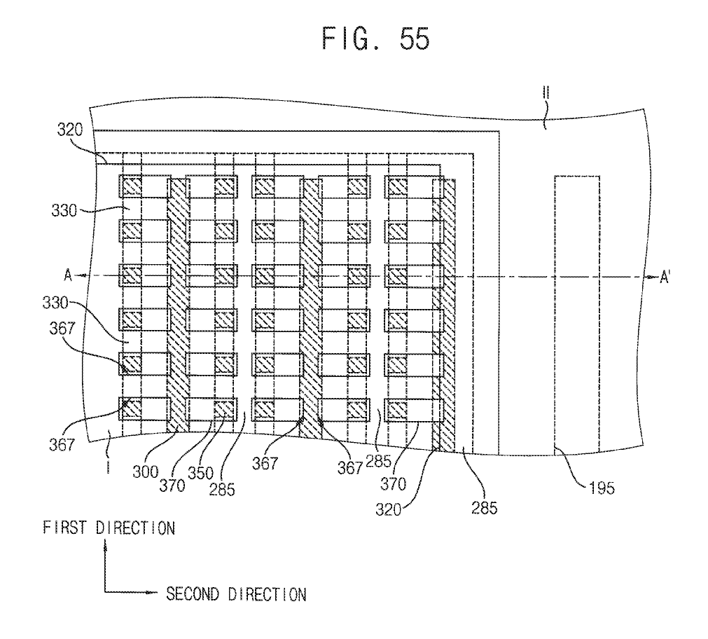

Referring to FIGS. 54 and 55, a fifth mask 370 may be formed on the pad layer 360, and the pad layer 360 may be patterned using the fifth mask 370 as an etching mask to form a plurality of pads 365.

In example embodiments, the pads 365 may cover the contact plugs 350, and each pad 365 may have a width wider than that of each contact plug 350 in the second direction.

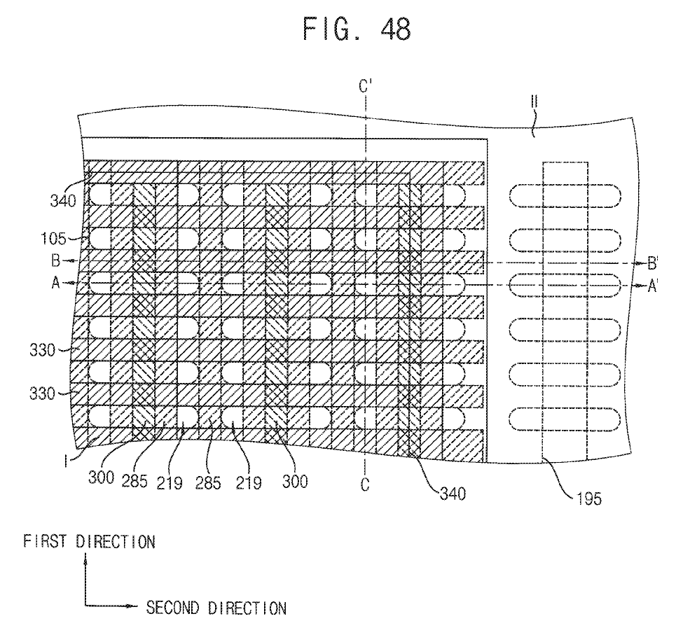

A space between the contact plugs 350 is shown as an eleventh opening 367 in FIGS. 47 and 48.

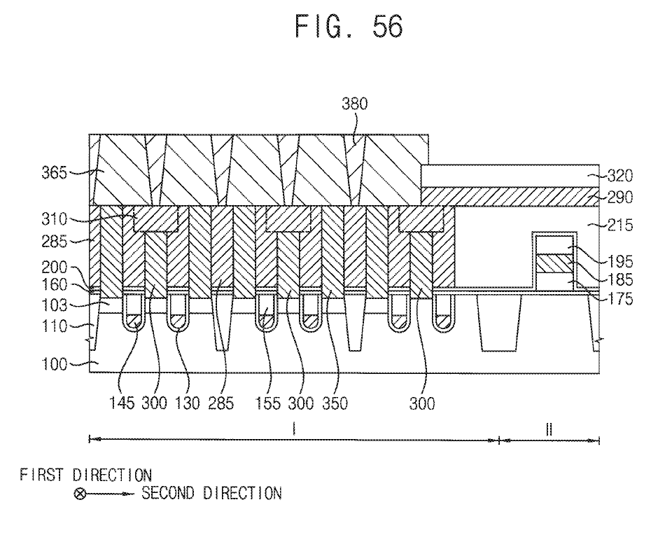

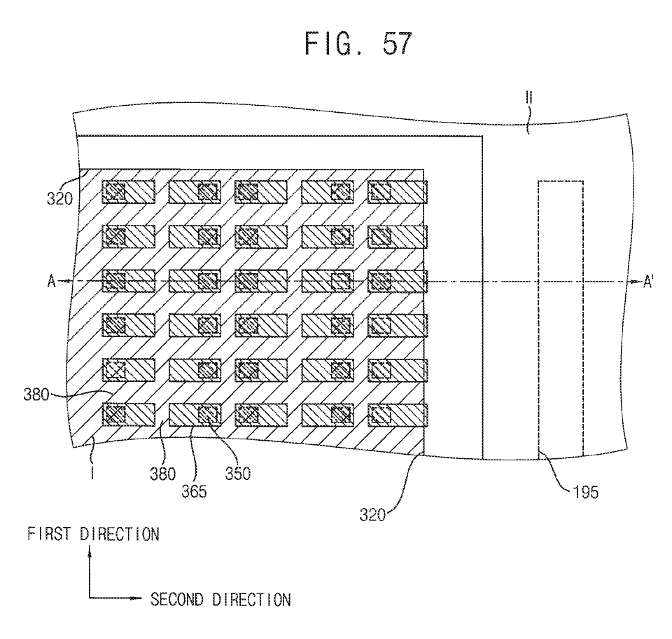

Referring to FIGS. 56 and 57, a second insulation layer 380 filling the eleventh opening 367 may be formed.

The second insulation layer 380 may include, for example, silicon nitride.

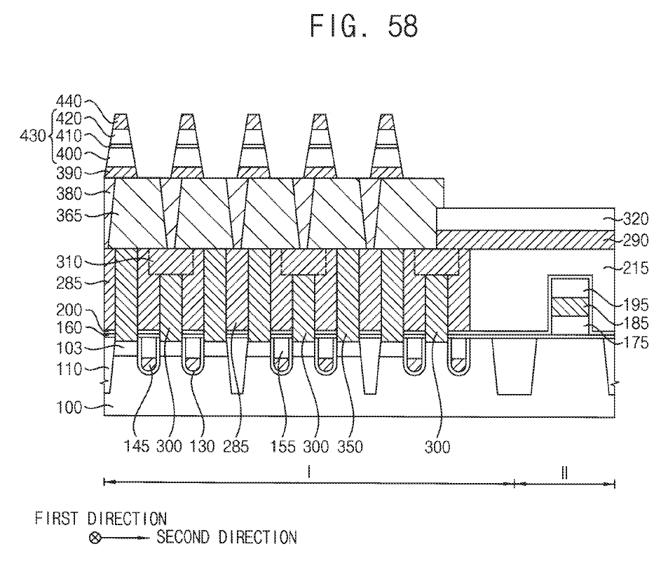

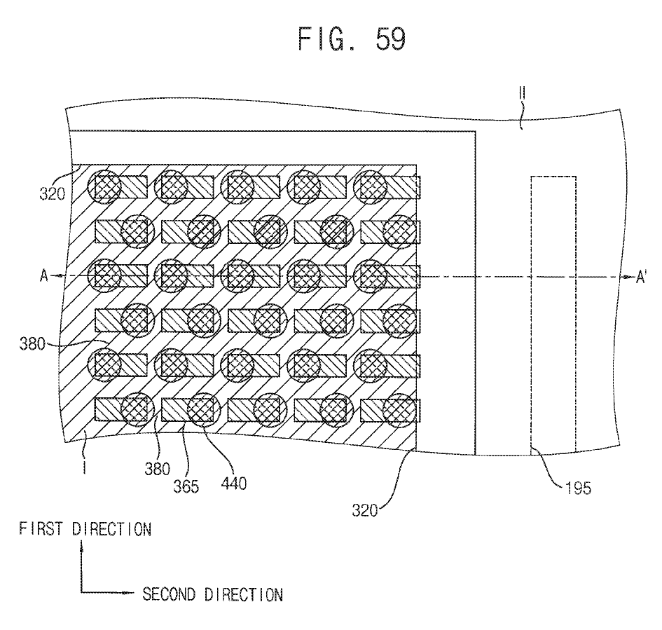

Referring to FIGS. 58 and 59, a lower electrode 390, a magnetic tunnel junction (MTJ) structure 430 and an upper electrode 440 sequentially stacked on each pad 365 may be formed on the second insulation layer 380. In an example embodiment, the MTJ structure 430 may include a fixed layer pattern 400, a tunnel barrier layer pattern 410 and a free layer pattern 420 sequentially stacked.

Processes substantially the same as or similar to those illustrated with reference to FIG. 2 may be performed to form the lower electrode 390, the MTJ structure 430 and the upper electrode 440.

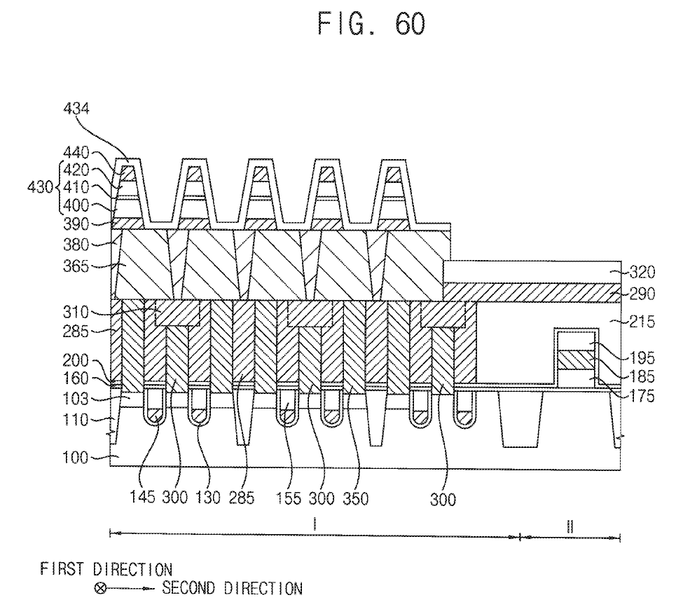

Referring to FIG. 60, a metal layer 434 may be formed to cover the lower electrode 390, the MTJ structure 430 and the upper electrode 440. Thus, the metal layer 434 may be formed on sidewalls of the lower electrode 390 and the MTJ structure 430, on a sidewall and a top surface of the upper electrode 440, and on the pad 365 and the second insulation layer 490. In example embodiments, the metal layer 434 may include aluminum.

A chemical vapor deposition (CVD) process, a plasma enhanced chemical vapor deposition (PECVD) process or an atomic layer deposition (ALD) process may be performed to form the metal layer 434.

Processes substantially the same as or similar to those illustrated with reference to FIGS. 4 to 7 may be performed to transform the metal layer 434 into a protection layer 432.

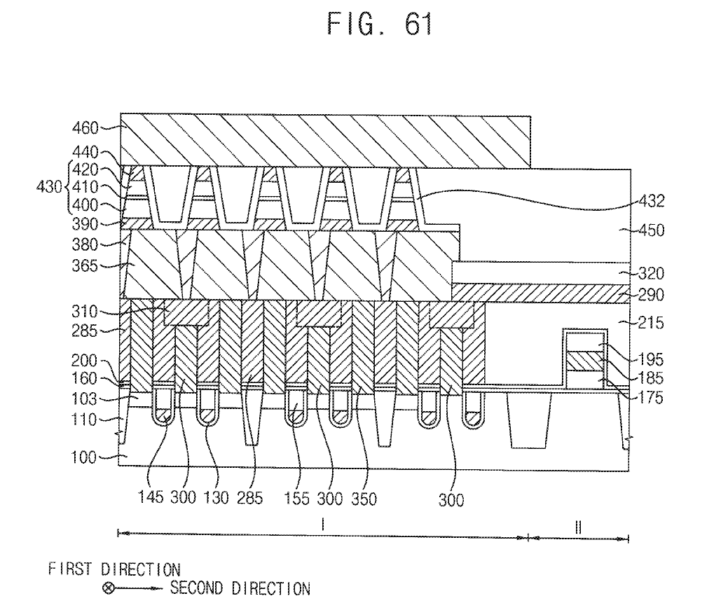

Referring to FIG. 61, a second insulating interlayer 450 may be formed on the pads 365, the second insulation layer 380 and the fourth mask 320 to cover sidewalls of the lower electrode 390, the MTJ structure 430 and the upper electrode 440, and a bit line 460 contacting the upper electrode 440 may be formed on the second insulating interlayer 450 to manufacture the MRAM device.

The second insulating interlayer 450 may include, for example, silicon oxide, and the bit line 460 may be formed to include, for example, a metal, a metal nitride and/or a metal silicide. In some embodiments, the bit line 460 may extend in the second direction, and a plurality of bit lines 460 may be arranged in the first direction.

As illustrated above, the metal layer 434 may be oxidized, so that the protection layer 432 may have an insulating property to prevent from electrical short between the fixed layer pattern 400 and the free layer pattern 420. The fluorination process may substantially prevent the free layer pattern 420 in the MTJ structure 430 covered by the metal layer 434 from being oxidized. Thus, the free layer pattern 420 may not substantially include oxygen, and the MTJ structure may have a high tunneling magneto resistance.

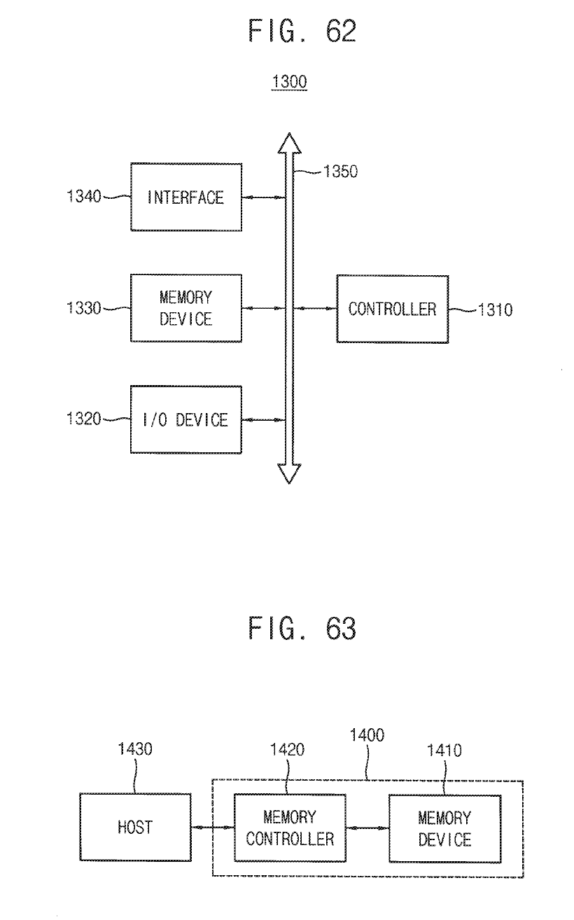

FIGS. 62 and 63 are block diagrams schematically illustrating electronic devices including a magnetic device according to example embodiments of the inventive concept.

Referring to FIG. 62, an electronic device 1300 including a magnetic device according to example embodiments of the inventive concept may be used in one of a personal digital assistant (PDA), a laptop computer, a mobile computer, a web tablet, a wireless phone, a cell phone, a digital music player, a wire or wireless electronic device, or a complex electronic device including at least two ones thereof. The electronic device 1300 may include a controller 1310, an input/output device 1320 such as a keypad, a keyboard, a display, a memory 1330, and a wireless interface 1340 that are combined to each other through a bus 1350. The controller 1310 may include, for example, at least one microprocessor, a digital signal process, a microcontroller or the like. The memory 1330 may be configured to store a command code to be used by the controller 1310 or a user data. The memory 1330 may include a semiconductor device according to example embodiments of the inventive concept. The electronic device 1300 may use a wireless interface 1340 configured to transmit data to or receive data from a wireless communication network using a RF signal. The wireless interface 1340 may include, for example, an antenna, a wireless transceiver and so on. The electronic system 1300 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, and so forth.

Referring to FIG. 63, a memory system including a semiconductor device according to example embodiments of the inventive concept will be described. The memory system 1400 may include a memory device 1410 for storing large amounts of data and a memory controller 1420. The memory controller 1420 controls the memory device 1410 so as to read data stored in the memory device 1410 or to write data into the memory device 1410 in response to a read/write request of a host 1430. The memory controller 1420 may include an address mapping table for mapping an address provided from the host 1430 (e.g., a mobile device or a computer system) into a physical address of the memory device 1410. The memory device 1410 may be a semiconductor device according to example embodiments of the inventive concept.

The present disclosure has been described in connection with a single MTJ structure. The principles of the present disclosure may also be applied to other magnetic memory elements such as spin valve or spin logic devices. The spin logic devices may be, for example, all-spin logic (ASL) device and non-volatile spin logic device.

In addition, the inventive concept of the present disclosure may be applied to the formation of system-on-chip (SOC) devices requiring a cache. In such cases, the SOC devices may include a MTJ element formed according to the present disclosure coupled to a microprocessor.

Further, the principles of the present disclosure can be applied to other magnetic memory element such as dual MTJ structures, where there are two reference layers with a free layer sandwiched therebetween.

As used herein, the term magnetic could include ferromagnetic, ferromagnetic or the like. Thus, the term “magnetic” or “ferromagnetic” includes, for example, ferromagnets and ferrimagnets. Various operations may be described as multiple discrete steps performed in a manner that is most helpful in understanding the invention. However, the order in which the steps are described does not imply that the operations are order-dependent or that the order that steps are performed must be the order in which the steps are presented.

With respect to the use of substantially any plural and/or singular terms herein, those having skill in the art can translate from the plural to the singular or from the singular to the plural as is appropriate to the context and/or application. The various singular/plural permutations may be expressly set forth herein for sake of clarity. The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing an MRAM device, the method comprising:
forming an MTJ structure on a substrate;
forming a metal layer to cover the MTJ structure; and
oxidizing and fluorinating the metal layer.

2. The method of claim 1, wherein the metal layer comprises aluminum.

3. The method of claim 1, wherein oxidizing and fluorinating the metal layer are performed by using oxygen plasma and a fluorine source, respectively.

4. The method of claim 3, wherein the fluorine source comprises polytetrafluoroethylene.

5. The method of claim 3, wherein prior to oxidizing and fluorinating the metal layer, the method further comprises loading the substrate on which the MTJ structure is formed into a chamber including the oxygen plasma and the fluorine source.

6. The method of claim 5, wherein the fluorine source includes polytetrafluoroethylene, and wherein the fluorine source has a hollow cylindrical shape.

7. The method of claim 5, wherein the fluorine source is disposed on an inner wall of the chamber.

8. The method of claim 7, wherein an internal diameter of the chamber and an external diameter of the fluorine source are substantially the same.

9. The method of claim 1, wherein prior to forming the metal layer, the method further comprises:
forming a lower electrode on the substrate; and
forming an upper electrode on the MTJ structure,
and wherein the metal layer is formed to cover the lower electrode, the MTJ structure and the upper electrode.
